(19) United States
(12) Patent Application Publication
(10) Pub. No.: US 2024/0357795 A1
(43) Pub. Date: Oct. 24, 2024

(54) SEMICONDUCTOR MEMORY DEVICES AND METHODS FOR MANUFACTURING THE SAME

(71) Applicant: SAMSUNG ELECTRONICS CO., LTD., Suwon-si (KR)

(72) Inventors: Tae Jin PARK, Suwon-si (KR); Hui-Jung KIM, Suwon-si (KR); Sang Jae PARK, Suwon-si (KR); Ki Seok LEE, Suwon-si (KR); Myeong-Dong LEE, Suwon-si (KR)

(21) Appl. No.: 18/513,011

(22) Filed: Nov. 17, 2023

(30) Foreign Application Priority Data
Apr. 20, 2023 (KR) 10-2023-0051837

(51) Int. Cl. H10B 12/00

(52) U.S. Cl. CPC H10B 12/315; H10B 12/0335

(57) ABSTRACT

There is provided a semiconductor memory device comprising: a substrate; a base insulating film on an upper surface of the substrate; a plurality of first conductive patterns on the base insulating film and spaced apart from each other, wherein the plurality of first conductive patterns extend in a first direction; a spacer structure on a side surface of each of the plurality of first conductive patterns; a barrier metal film on a side surface of the spacer structure, wherein the barrier metal film extends through the base insulating film to be electrically connected to the substrate; a filling metal film on the barrier metal film, wherein the filling metal film fills at least a portion of a space between adjacent ones of the plurality of first conductive patterns; and a capacitor structure on the filling metal film, wherein the capacitor structure is electrically connected to the filling metal film.

### CROSS-REFERENCE TO RELATED APPLICATION

This application claims priority from Korean Patent Application No. 10-2023-0051837 filed on Apr. 20, 2023 in the Korean Intellectual Property Office, and all the benefits accruing therefrom under 35 U.S.C. 119, the contents of which in its entirety are herein incorporated by reference.

### BACKGROUND

The present disclosure relates to semiconductor memory devices and methods for manufacturing the same. More specifically, the present disclosure relates to semiconductor memory devices, including a capacitor and methods for manufacturing the same.

As semiconductor memory devices become increasingly highly integrated, individual circuit patterns are becoming more miniaturized to implement a larger number of semiconductor memory devices in the same area. However, the miniaturization of individual circuit patterns increases process difficulty and causes defects.

### SUMMARY

Embodiments of the present disclosure provide semiconductor memory devices with improved integration, performance, and reliability.

Embodiments of the present disclosure provide methods for manufacturing semiconductor memory devices with improved integration, performance, and reliability.

According to some embodiments of the present disclosure, there is provided a semiconductor memory device comprising: a substrate; a base insulating film on an upper surface of the substrate; a plurality of first conductive patterns on the base insulating film and spaced apart from each other, wherein the plurality of first conductive patterns extend in a first direction; a spacer structure on a side surface of each of the plurality of first conductive patterns; a barrier metal film on a side surface of the spacer structure, wherein the barrier metal film extends through the base insulating film to be electrically connected to the substrate; a filling metal film on the barrier metal film, wherein the filling metal film fills at least a portion of a space between adjacent ones of the plurality of first conductive patterns; and a capacitor structure on the filling metal film, wherein the capacitor structure is electrically connected to the filling metal film.

According to some embodiments of the present disclosure, there is provided a semiconductor memory device comprising: a substrate; a first conductive pattern on the substrate, wherein the first conductive pattern extends in a first direction; a spacer structure on a side surface of the first conductive pattern; an insulating fence on the substrate, wherein the insulating fence extends in a second direction intersecting the first direction; a barrier metal film on an upper surface of the substrate and a side surface of the spacer structure, wherein a side surface of the insulating fence includes a portion that is exposed from the barrier metal film; a filling metal film on the barrier metal film, wherein the filling metal film is on the side surface of the spacer structure and the side surface of the insulating fence; and a capacitor structure on the filling metal film, wherein the capacitor structure is electrically connected to the filling metal film.

According to some embodiments of the present disclosure, there is provided a semiconductor memory device comprising: a substrate including an active area that is adjacent an element isolation pattern; a first conductive pattern on an upper surface of the substrate, wherein the first conductive pattern extends in a first direction; a direct contact electrically connecting the active area to the first conductive pattern; a spacer structure on a side surface of the first conductive pattern; an insulating fence on the substrate, wherein the insulating fence extends in a second direction intersecting the first direction; a landing contact on a side surface of the spacer structure and a side surface of the insulating fence, wherein the landing contact is in contact with the active area; a capacitor structure on the landing contact, wherein the capacitor structure is electrically connected to the landing contact; and a second conductive pattern extending in the second direction and extending across a portion of the active area between the direct contact and the landing contact, wherein the landing contact includes: a barrier metal film on the upper surface of the substrate and the side surface of the spacer structure; and a filling metal film on the barrier metal film, wherein the filling metal film is on the side surface of the spacer structure and the side surface of the insulating fence.

Embodiments of the present disclosure are not limited to the above-mentioned embodiments. Other embodiments and advantages that are not mentioned according to the present disclosure may be understood based on following descriptions and may be more clearly understood based on embodiments taken in conjunction with the accompanying drawings according to the present disclosure. Further, it will be easily understood that the embodiments and advantages according to the present disclosure may be realized using means shown in the claims and combinations thereof.

### BRIEF DESCRIPTION OF DRAWINGS

The above and other aspects and features of the present disclosure will become more apparent by describing in detail illustrative embodiments thereof with reference to the attached drawings, in which:

FIG. 1 is a layout diagram for illustrating a semiconductor memory device according to some embodiments.

FIG. 2 is a cross-sectional view taken along A-A′ of FIG. 1 according to some embodiments.

FIG. 3 is a cross-sectional view taken along B-B′ of FIG. 1 according to some embodiments.

FIG. 4 is a cross-sectional view taken along A-A′ of FIG. 1 according to some embodiments.

FIG. 5 is a cross-sectional view taken along B-B′ of FIG. 1 according to some embodiments.

FIG. 6 is a layout diagram for illustrating a semiconductor memory device according to some embodiments.

FIG. 7 is a cross-sectional view taken along C-C′ of FIG. 6 according to some embodiments.

FIG. 8 is a cross-sectional view taken along D-D′ of FIG. 6 according to some embodiments.

FIG. 9 is a cross-sectional view taken along C-C′ of FIG. 6 according to some embodiments.

FIG. 10 is a cross-sectional view taken along D-D′ of FIG. 6 according to some embodiments.

FIG. 11 to FIG. 35 are diagrams of intermediate structures corresponding to intermediate steps for illustrating a method for a manufacturing a semiconductor memory device according to some embodiments.

FIG. 36 to FIG. 44 are diagrams of intermediate structures corresponding to intermediate steps for illustrating a method for manufacturing a semiconductor memory device according to some embodiments.

### DETAILED DESCRIPTIONS

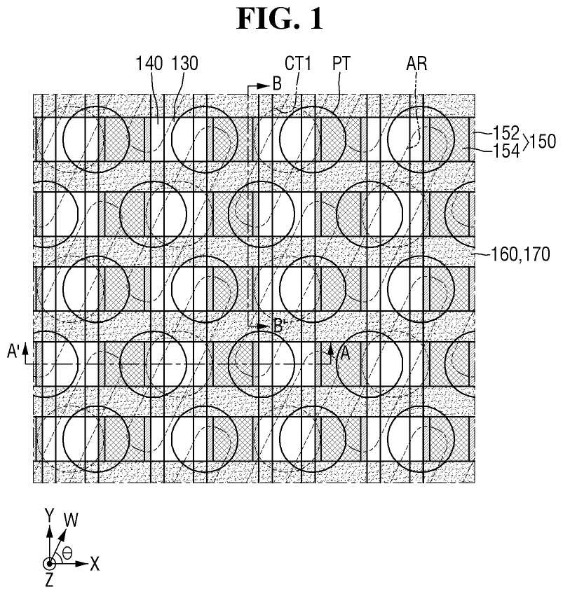

Hereinafter, a semiconductor memory device according to some embodiments are described with reference to FIGS. 1 to 10.

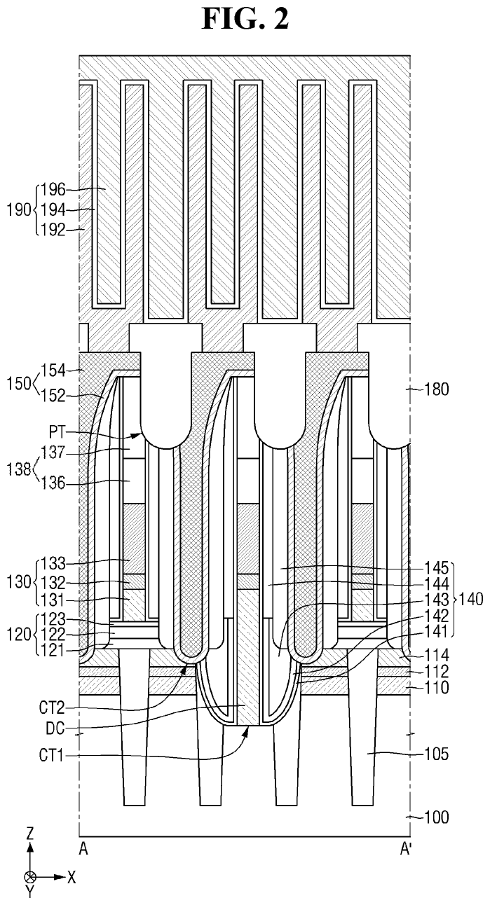

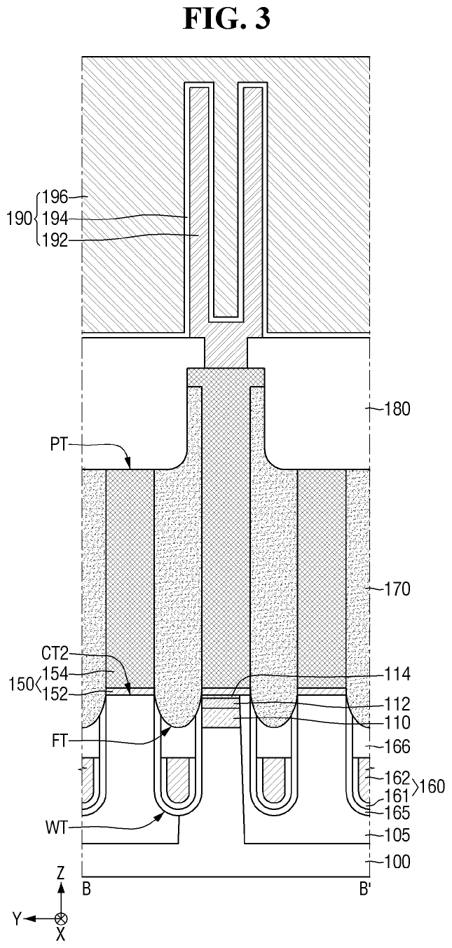

FIG. 1 is a layout diagram for illustrating a semiconductor memory device according to some embodiments. FIG. 2 is a cross-sectional view taken along A-A′ of FIG. 1 according to some embodiments. FIG. 3 is a cross-sectional view taken along B-B′ of FIG. 1 according to some embodiments.

Referring to FIGS. 1 to 3, a semiconductor memory device according to some embodiments may include a substrate 100, an element isolation pattern 105, a base insulating film 120, a first conductive pattern 130, a direct contact DC, a first capping pattern 138, a spacer structure 140, a landing contact 150, a second conductive pattern 160, a gate dielectric film 165, a second capping pattern 166, an insulating fence 170, an isolation insulating film 180 and a capacitor structure 190.

The substrate 100 may have a structure in which abase substrate and an epitaxial layer are stacked. However, the present disclosure is not limited thereto. The substrate 100 may include, for example, silicon, gallium arsenide, and/or silicon germanium. The substrate 100 may be a SOI (Silicon On Insulator) substrate. By way of example, an example in which the substrate 100 is a silicon substrate is described below.

The substrate 100 may include an active area AR. As a design rule of a semiconductor memory device decreases, the active area AR may be formed as a bar extending in a diagonal direction. For example, the active area AR may extend as a bar in a third direction W in a plane (e.g., a XY plane) including a first direction Y and a second direction X. The first direction Y and the second direction X may be horizontal directions parallel with an upper surface of the substrate 100. The first direction Y and the second direction X may intersect (e.g., perpendicular) to each other. In some embodiments, the third direction W may have an acute angle θ with respect to the second direction X. The acute angle θ may be, for example, about 60°. However, the present disclosure is not limited thereto.

The active areas AR may extend in a parallel manner to each other. In some embodiments, a center (e.g., center portion) of one active area AR among a plurality of active areas AR may be disposed adjacent to a distal end of another active area AR among the plurality of active areas AR.

The active area AR may have a portion containing impurities which may act as a source/drain area. In some embodiments, the center (e.g., center portion) of the active area AR may be electrically connected (e.g., connected) to the first conductive pattern 130 via the direct contact DC, while each of both opposing ends of the active area AR may be electrically connected (e.g., connected) to the capacitor structure 190 via the landing contact 150.

The element isolation pattern 105 may be disposed in the substrate 100 so as to define the active area AR. For example, the element isolation pattern 105 may be adjacent to the active area AR. In FIG. 2 and FIG. 3, it is shown that a side surface of the element isolation pattern 105 has an inclination. However, this is only a feature due to a process. The present disclosure is not limited thereto.

The element isolation pattern 105 may include an insulating material, for example, silicon oxide, silicon nitride, silicon oxynitride, silicon oxycarbonitride, and/or combinations thereof. However, the present disclosure is not limited thereto. The element isolation pattern 105 may be a single film made of one type of an insulating material, or may be a stack of multi-films made of a combination of several types of insulating materials.

The base insulating film 120 may be formed on the substrate 100 and the element isolation pattern 105. The base insulating film 120 may be on (e.g., extend along) the upper surface of the substrate 100 and/or an upper surface of the element isolation pattern 105. The upper surface of the substrate 100 and the upper surface of the element isolation pattern 105 may be coplanar (e.g., substantially coplanar). However, the embodiments of the present disclosure are not limited thereto.

The base insulating film 120 may be a single film or a stack of multi-films. For example, the base insulating film 120 may include a first insulating film 121, a second insulating film 122, and a third insulating film 123 sequentially stacked on the substrate 100 and the element isolation pattern 105. In some embodiments, the first insulating film 121 may include a silicon oxide film. The second insulating film 122 may include a material having an etch selectivity with the first insulating film 121. For example, the second insulating film 122 may include a silicon nitride film. The third insulating film 123 may include a material having a dielectric constant lower than that of the second insulating film 122. For example, the third insulating film 123 may include a silicon oxide film.

In some embodiments, a base semiconductor film 110, a base silicide film 112, and a base metal film 114 may be disposed between the substrate 100 and the base insulating film 120. The base semiconductor film 110, the base silicide film 112, and the base metal film 114 may be sequentially stacked on the substrate 100. The element isolation pattern 105 may define the active area AR including the base semiconductor film 110, the base silicide film 112, and the base metal film 114. For example, the element isolation pattern 105 may be adjacent to the base semiconductor film 110, the base silicide film 112, and the base metal film 114.

The base semiconductor film 110 may be on (e.g., extend along) the upper surface of the substrate 100. The base semiconductor film 110 may include a semiconductor material doped with impurities. For example, the base semiconductor film 110 may include polysilicon containing impurities. In some embodiments, the base semiconductor film 110 may include a polysilicon film doped with p-type impurities, such as B, In, Ga, or Al. In some embodiments, the base semiconductor film 110 may include a polysilicon film doped with n-type impurities, for example, P, Sb, or As.

The base silicide film 112 may be on (e.g., extend along) an upper surface of the base semiconductor film 110. The base silicide film 112 may include, for example, a metal silicide material such as nickel silicide, cobalt silicide, tungsten silicide, titanium silicide, niobium silicide, or tantalum silicide.

The base metal film 114 may be on (e.g., extend along) an upper surface of the base silicide film 112. The base metal film 114 may include, for example, a metal material such as titanium (Ti), tantalum (Ta), tungsten (W), nickel (Ni), cobalt (Co), or platinum (Pt).

In some embodiments, the base silicide film 112 may be formed by the reaction of elements included in the base metal film 114 and the base semiconductor film 110.

The first conductive pattern 130 may be formed on the base insulating film 120. That is, the base insulating film 120 may be disposed between the substrate 100 and the first conductive pattern 130 and/or between the element isolation pattern 105 and the first conductive pattern 130. The first conductive pattern 130 may extend (e.g., extend in an elongate manner) in the first direction Y and in a parallel manner to the upper surface of the substrate 100. For example, the first conductive pattern 130 may obliquely intersect the active area AR and perpendicularly intersect the second conductive pattern 160. A plurality of first conductive patterns 130 may be spaced apart from each other in the second direction X and may extend side by side (e.g., in a parallel manner to each other) in the first direction Y. The first conductive patterns 130 may act as bit lines of the semiconductor memory device. In some embodiments, the plurality of first conductive pattern 130 may be spaced apart from each other by an equal spacing.

The first conductive pattern 130 may be a single film or may be a stack of multi-films. For example, the first conductive pattern 130 may include a first conductive line 131, a second conductive line 132, and a third conductive line 133 sequentially stacked on the substrate 100. Each of the first conductive line 131, the second conductive line 132, and the third conductive line 133 may include a conductive material, for example, polysilicon, TiN, TiSiN, tungsten, tungsten silicide, and/or combinations thereof. However, the present disclosure is not limited thereto. In some embodiments, the first conductive line 131 may include polysilicon, the second conductive line 132 may include TiSiN, and the third conductive line 133 may include tungsten.

The direct contact DC may be formed on the substrate 100 and the element isolation pattern 105. The direct contact DC may electrically connect (e.g., connect) the active area AR to the first conductive pattern 130. For example, a first contact trench CT1 may extend through the base insulating film 120 so as to expose a first portion of the active area AR. The direct contact DC may be formed in the first contact trench CT1 so as to electrically connect (e.g., connect) the first portion of the active area AR to the first conductive pattern 130. The first portion of the active area AR electrically connected (e.g., connected) to the direct contact DC may act as a first source/drain area of a semiconductor device using the second conductive pattern 160 as a gate electrode.

In some embodiments, the first contact trench CT1 may expose the center (e.g., the center portion) of the active area AR. Accordingly, the direct contact DC may contact the center (e.g., center portion) of the active area AR. In some embodiments, a portion of the first contact trench CT1 may overlap (e.g., overlap in the fourth direction Z) a portion of the element isolation pattern 105. Accordingly, the first contact trench CT1 may expose a portion of the element isolation pattern 105 as well as a portion (e.g., the center portion) of the active area AR.

In some embodiments, a width of the direct contact DC in a horizontal direction (e.g., first and/or second directions Y and/or X) may be smaller than a width of the first contact trench CT1 in the horizontal direction. For example, the direct contact DC may only contact a portion of the substrate 100 exposed through the first contact trench CT1. In some embodiments, a width of the first conductive pattern 130 in the horizontal direction may be smaller than a width of the first contact trench CT1 in the horizontal direction. For example, the width of the first conductive pattern 130 in the horizontal direction may be the same as that of the direct contact DC in the horizontal direction.

In some embodiments, the first contact trench CT1 may extend through the base semiconductor film 110, the base silicide film 112, and the base metal film 114 so as to expose the substrate 100 (e.g., a portion of the substrate 100). The direct contact DC may be formed in the first contact trench CT1 and may contact the active area AR of the substrate 100.

The direct contact DC may include a conductive material, for example, polysilicon, TiN, TiSiN, tungsten, tungsten silicide, and/or combinations thereof. However, the present disclosure is not limited thereto. In some embodiments, the direct contact DC may include polysilicon.

The first capping pattern 138 may be formed on the first conductive pattern 130. The first capping pattern 138 may be on (e.g., extend along) an upper surface of the first conductive pattern 130. The first capping pattern 138 may be a single film or may be a stack of multiple films. For example, the first capping pattern 138 may include the first capping line 136 and the second capping line 137 sequentially stacked on the first conductive pattern 130. Each of the first capping line 136 and the second capping line 137 may include an insulating material, for example, silicon oxide, silicon nitride, silicon oxynitride, silicon oxycarbonitride, and/or combinations thereof. However, the present disclosure is not limited thereto. In some embodiments, each of the first capping line 136 and the second capping line 137 may include a silicon nitride film.

In some embodiments, an etch stop layer may be disposed between the first capping line 136 and the second capping line 137. The etch stop layer may include, for example, SiN. However, the present disclosure is not limited thereto.

The spacer structure 140 may be formed on a side surface of the first conductive pattern 130. The spacer structure 140 may be on a side surface of the first capping pattern 138. The spacer structure 140 may extend along a side surface of the first conductive pattern 130 and a side surface of the first capping pattern 138. In some embodiments, a vertical level of an upper surface of the spacer structure 140 may be equal to or lower than that of an upper surface (e.g., an uppermost surface) of the first capping pattern 138. A vertical level of an element may mean a relative location (e.g., a distance) of the element from the lower surface of the substrate 100 in a fourth direction Z based on the drawings. For example, a distance of an upper surface of the spacer structure 140 from the lower surface of the substrate 100 in the fourth direction Z may be equal to or closer than that of the upper surface (e.g., the uppermost surface) of the first capping pattern 138. The fourth direction Z may be a vertical direction perpendicular to the first direction Y and the second direction X. The fourth direction Z may be perpendicular to the upper surface of the substrate 100.

The spacer structure 140 may include an insulating material, for example, silicon oxide, silicon nitride, silicon oxynitride, silicon oxycarbonitride, and/or combinations thereof. However, the present disclosure is not limited thereto. In some embodiments, the spacer structure 140 may be a stack of multi-films made of a combination of different types of insulating materials. For example, the spacer structure 140 may include a base spacer 141, a first lower spacer 142, a second lower spacer 143, a first side spacer 144, and a second side spacer 145.

The base spacer 141 may be formed on a side surface of the first conductive pattern 130. For example, the base spacer 141 may conformally extend along a profile of the side surface of the first conductive pattern 130 and at least a portion of the side surface of the first capping pattern 138. The base spacer 141 may be on a side surface of the direct contact DC. In some embodiments, the base spacer 141 may be an innermost spacer of the spacer structure 140 that contacts the first conductive pattern 130 and the direct contact DC.

In some embodiments, in an area where the first contact trench CT1 is not formed, the base spacer 141 may extend along the side surface of the first conductive pattern 130 and at least a portion of an upper surface of the base insulating film 120. In some embodiments, in an area where the first contact trench CT1 is formed, the base spacer 141 may extend along the side surface of the first conductive pattern 130, a side surface of the direct contact DC, and the first contact trench CT1 (e.g., an inner surface of the first contact trench CT1).

The first lower spacer 142 may be formed on the base spacer 141 in the first contact trench CT1. For example, the first lower spacer 142 may conformally extend along a profile of the base spacer 141 in the first contact trench CT1.

The second lower spacer 143 may be formed on the first lower spacer 142 in the first contact trench CT1. For example, the second lower spacer 143 may fill an area of the first contact trench CT1 remaining after the base spacer 141 and the first lower spacer 142 have been formed in the first contact trench CT1.

The first side spacer 144 may be formed on an outer side surface of the base spacer 141. In some embodiments, the first side spacer 144 may be formed on the first lower spacer 142 and the second lower spacer 143. For example, the first side spacer 144 may conformally extend along a profile of the side surface of the first conductive pattern 130 and at least a portion of the side surface of the first capping pattern 138.

The second side spacer 145 may be formed on an outer side surface of the first side spacer 144. In some embodiments, the first side spacer 144 may be formed on the second lower spacer 143. For example, the second side spacer 145 may conformally extend along a profile of the side surface of the first conductive pattern 130 and at least a portion of the side surface of the first capping pattern 138. In some embodiments, the second side spacer 145 may be an outermost spacer of the spacer structure 140 in contact with the landing contact 150.

In some embodiments, a vertical level of a lower surface of the second side spacer 145 may be lower than that of an upper surface (e.g., an uppermost surface) of the second lower spacer 143.

Each of the base spacer 141, the first lower spacer 142, the second lower spacer 143, the first side spacer 144 and the second side spacer 145 may include an insulating material, for example, silicon oxide, silicon nitride, silicon oxynitride, silicon oxycarbonitride and/or combinations thereof. However, the present disclosure is not limited thereto.

In some embodiments, the first lower spacer 142 may include a different material than that of the base spacer 141 and/or the second lower spacer 143. For example, the first lower spacer 142 may include an insulating material having a dielectric constant lower than that of the base spacer 141 and/or the second lower spacer 143. In some embodiments, the first lower spacer 142 may include a silicon oxide film, and each of the base spacer 141 and the second lower spacer 143 may include a silicon nitride film.

In some embodiments, the first side spacer 144 may include a different material than that of the base spacer 141 and/or the second side spacer 145. For example, the first side spacer 144 may include an insulating material having a dielectric constant lower than that of the base spacer 141 and/or the second side spacer 145. In some embodiments, the first side spacer 144 may include a silicon oxide film, and each of the base spacer 141 and the second side spacer 145 may include a silicon nitride film.

The second conductive pattern 160 may be formed on the substrate 100 and the element isolation pattern 105. The second conductive pattern 160 may extend in a parallel manner to the upper surface of the substrate 100 and may extend (e.g., extend in an elongate manner) in the second direction X intersecting the first direction Y. In some embodiments, the second conductive pattern 160 may intersect the active area AR between the direct contact DC and the landing contact 150. For example, the second conductive pattern 160 may obliquely intersect the active area AR and perpendicularly intersect the first conductive pattern 130. A plurality of second conductive patterns 160 may be spaced apart from each other in the first direction Y and extend side by side (e.g., in a parallel manner to each other) in the second direction X. The second conductive patterns 160 may act as word lines of the semiconductor memory device. In some embodiments, the plurality of second conductive patterns 160 may be spaced apart from each other by an equal spacing.

In some embodiments, two second conductive patterns 160 among the plurality of second conductive patterns 160 may intersect one active area AR. For example, two second conductive patterns 160 may be respectively disposed on both opposing sides of the direct contact DC that is connected to the center (e.g., the center portion) of one active area AR. These two second conductive patterns 160 may share one direct contact DC. For example, a second conductive pattern 160 among the plurality of second conductive patterns 160 may extend to across a portion of the substrate between the filling metal film 154 and the direct contact DC.

The second conductive pattern 160 may be a single film or may be a stack of multi-films. For example, the second conductive pattern 160 may include a fourth conductive line 161 and a fifth conductive line 162 sequentially stacked on the substrate 100. Each of the fourth conductive line 161 and the fifth conductive line 162 may include a conductive material, for example, polysilicon, TiN, TiSiN, tungsten, tungsten silicide, and/or combinations thereof. However, the present disclosure is not limited thereto.

A gate dielectric film 165 may be disposed between the substrate 100 and the second conductive pattern 160. The gate dielectric film 165 may be disposed between the element isolation pattern 105 and the second conductive pattern 160. The gate dielectric film 165 may include, for example, silicon oxide, silicon oxynitride, silicon nitride, and/or a high-k material with a higher dielectric constant than that of silicon oxide. However, the present disclosure is not limited thereto.

The second capping pattern 166 may be formed on the second conductive pattern 160. The second capping pattern 166 may be on (e.g., extend along) an upper surface of the second conductive pattern 160. The second capping pattern 166 may include, for example, an insulating material, such as silicon oxide, silicon nitride, silicon oxynitride, silicon oxycarbonitride, and/or combinations thereof. However, the present disclosure is not limited thereto. The second capping pattern 166 may be a single film or a stack of multi-films made of a combination of various types of insulating materials.

In some embodiments, the second conductive pattern 160 may be in (e.g., embedded in) the substrate 100. For example, a gate trench WT extending in the second direction X may be formed in the substrate 100 and the element isolation pattern 105. The gate dielectric film 165 may be disposed in the gate trench WT. The gate dielectric film 165 may extend along a profile of the gate trench WT. The second conductive pattern 160 may fill a portion of the gate trench WT while being disposed on the gate dielectric film 165. The second capping pattern 166 may fill another portion of the gate trench WT while being disposed on the gate dielectric film 165 and the second conductive pattern 160. In this case, a vertical level of an upper surface of the second conductive pattern 160 may be lower than that of the upper surface of the substrate 100.

In some embodiments, the gate trench WT may extend through the base semiconductor film 110, the base silicide film 112, and the base metal film 114. In some embodiments, a vertical level of an upper surface of the second conductive pattern 160 may be lower than that of a lower surface of the base semiconductor film 110.

The insulating fence 170 may be formed on the substrate 100 and the element isolation pattern 105. The insulating fence 170 may intersect the first conductive pattern 130 and/or the spacer structure 140. For example, a fence trench FT extending (e.g., extending in an elongate manner) in the second direction X may be formed on the substrate 100 and the element isolation pattern 105, and the insulating fence 170 may be formed in the fence trench FT. A plurality of insulating fences 170 may be spaced apart from each other in the first direction Y and extend side by side (e.g., in a parallel manner to each other) in the second direction X. In some embodiments, a plurality of insulating fences 170 may be spaced apart from each other by an equal spacing.

The insulating fence 170 may include an insulating material, for example, silicon oxide, silicon nitride, silicon oxynitride, silicon oxycarbonitride, and/or a combination thereof. However, the present disclosure is not limited thereto. In some embodiments, the insulating fence 170 may include a silicon nitride film.

In some embodiments, a vertical level of an upper surface (e.g., an uppermost surface) of the insulating fence 170 may be higher than a vertical level of the upper surface (e.g., the uppermost surface) of the first capping pattern 138.

In some embodiments, the insulating fence 170 may overlap the second conductive pattern 160 in the fourth direction Z. For example, the insulating fence 170 may be formed on the second capping pattern 166. As used herein, “an element A overlapping an element B in a direction X” (or similar language) means that there is at least one line that extends in the direction X and intersects both the elements A and B.

Referring to FIG. 3, a width of the insulating fence 170 in a horizontal direction (e.g., in the first direction Y) may be the same as a width of the gate trench WT in the horizontal direction. However, this is only an example, and the width of the insulating fence 170 in the horizontal direction may be larger or smaller than the width of the gate trench WT in the horizontal direction.

The landing contact 150 may be formed on the substrate 100 and the element isolation pattern 105. In some embodiments, the landing contact 150 may be formed on the side surface of the first conductive pattern 130 and a side surface of the insulating fence 170. For example, a plurality of first conductive patterns 130 and a plurality of insulating fences 170 intersecting each other may respectively define a plurality of isolated areas therebetween. The landing contact 150 may be formed in each of the isolated areas. The landing contact 150 may be spaced from the first conductive pattern 130 via the spacer structure 140. That is, the spacer structure 140 may electrically insulate the first conductive pattern 130 and the landing contact 150 from each other.

The landing contact 150 may electrically connect (e.g., connect) the active area AR to the capacitor structure 190. For example, a second contact trench CT2 extending through the base insulating film 120 so as to expose a second portion of the active area AR may be formed between each of the plurality of first conductive patterns 130 and each of the plurality of insulating fences 170. The landing contact 150 may be formed in the second contact trench CT2 so as to electrically connect (e.g., connect) the second portion of the active area AR to the capacitor structure 190. The second portion of the active area AR electrically connected (e.g., connected) to the landing contact 150 may act as a second source/drain area of a semiconductor device using the second conductive pattern 160 as a gate electrode.

In some embodiments, the second contact trench CT2 may expose each of both opposing ends of each active area AR. Accordingly, the landing contact 150 may be electrically connected (e.g., connected) to each of both opposing ends of the active area AR. In some embodiments, a portion of the second contact trench CT2 may overlap (e.g., overlap in the fourth direction Z) a portion of the element isolation pattern 105. Accordingly, the second contact trench CT2 may expose a portion of the element isolation pattern 105 as well as a portion of the active area AR.

In some embodiments, the second contact trench CT2 may expose the base metal film 114. For example, the second contact trench CT2 may include a recess (e.g., concavely recessed portion) in an upper portion of the base metal film 114. The landing contact 150 may be formed in the second contact trench CT2 and in contact with the base metal film 114.

In some embodiments, the second contact trench CT2 may not expose the base silicide film 112. For example, a vertical level of a lowermost surface of the second contact trench CT2 may be higher than that of an upper surface of the base silicide film 112.

The landing contact 150 may include a barrier metal film 152 and a filling metal film 154 sequentially stacked in the second contact trench CT2.

The barrier metal film 152 may be disposed on (e.g., conformally extend along) a profile of a portion of the second contact trench CT2. The barrier metal film 152 may extend through the base insulating film 120 so as to be electrically connected to the substrate 100. In some embodiments, the barrier metal film 152 may be disposed on (e.g., conformally extend along) the side surface of the spacer structure 140 and the upper surface (e.g., the uppermost surface) of the first capping pattern 138. In some embodiments, the barrier metal film 152 may conformally extend along a portion of the upper surface of the substrate 100 between adjacent ones of the plurality of first conductive patterns 130 and a portion of the upper surface of the substrate 100 between adjacent ones of the plurality of insulating fences 170. In some embodiments, the barrier metal film 152 may be disposed on (e.g., conformally extend along) the upper surface of the base metal film 114. For example, the barrier metal film 152 may be in contact (e.g., direct contact) with the base metal film 114.

The barrier metal film 152 may not extend along the side surface of the insulating fence 170. However the inventive concepts of the present application are not limited thereto. For example, the barrier metal film 152 may contact a side surface of the insulating fence 170. The insulating fence 170 may include at least a portion (e.g., a portion of a side surface) that is not in contact with the barrier metal film 152. At least a portion of a side surface of the insulating fence 170 may be exposed from the barrier metal film 152. A side surface of the insulating fence 170 may be in contact with the filling metal film 154. In some embodiments, a vertical level of a lowermost portion of the insulating fence 170 may be lower than that of a lower surface of the barrier metal film 152. For example, a lower portion of the insulating fence 170 may extend through the barrier metal film 152 and thus contact the second capping pattern 166.

The barrier metal film 152 may include, for example, a metal or a metal nitride to prevent diffusion of elements included in the filling metal film 154. For example, the barrier metal film 152 may include, for example, titanium (Ti), tantalum (Ta), tungsten (W), nickel (Ni), cobalt (Co), platinum (Pt), alloys thereof, and/or nitrides thereof. However, the present disclosure is not limited thereto. In some embodiments, the barrier metal film 152 may include a titanium nitride film.

The filling metal film 154 may be formed on the barrier metal film 152. The filling metal film 154 may be formed on the side surface of the spacer structure 140 and the side surface of the insulating fence 170. Accordingly, the filling metal film 154 may at least partially fill a space between adjacent ones of the plurality of first conductive patterns 130 and a space between adjacent ones of the plurality of insulating fences 170.

The filling metal film 154 may include a conductive metal material, for example, tungsten (W), molybdenum (Mo), ruthenium (Ru), cobalt (Co), nickel (Ni), and/or combinations thereof. However, the present disclosure is not limited thereto. In some embodiments, the filling metal film 154 may include tungsten (W).

In some embodiments, a vertical level of and an upper surface (e.g., an uppermost surface) of the filling metal film 154 may be higher than a vertical level of the upper surface (e.g., the uppermost surface) of the first capping pattern 138. The filling metal film 154 may cover at least a portion of the upper surface (e.g., the uppermost surface) of the spacer structure 140 and/or at least a portion of the upper surface (e.g., the uppermost surface) of the first capping pattern 138.

In some embodiments, a vertical level of the upper surface (e.g., the uppermost surface) of the filling metal film 154 may be higher than a vertical level of an upper surface (e.g., an uppermost surface) of the insulating fence 170. The filling metal film 154 may cover at least a portion of the upper surface (e.g., the uppermost surface) of the insulating fence 170.

In some embodiments, the filling metal film 154 may be a unitary structure that is integrally formed and may extend from a vertical level lower than that of a lower surface of the first conductive pattern 130 (for example, a lower surface of the first conductive line 131) to a vertical level higher than that of the upper surface of the insulating fence 170. For example, the filling metal film 154 may extend from below a lower surface of the first conductive pattern 130, relative to the upper surface of the substrate 100 to beyond an upper surface of the insulating fence 170, relative to the upper surface of the substrate 100. A unitary structure herein may refer to a structure without a visible boundary between two or more sub-elements thereof.

The landing contacts 150 may be formed as a plurality of isolated areas spaced apart from each other and defined by the plurality of first capping patterns 138, the plurality of spacer structures 140, and the plurality of insulating fences 170. In some embodiments, the landing contacts 150 may be spaced apart from each other by the plurality of first capping patterns 138, the plurality of spacer structures 140, and the plurality of insulating fences 170. For example, a pad trench PT for isolating upper portions of the landing contacts 150 from each other may be formed. The pad trench PT may extend from the upper surface of the landing contact 150, while a vertical level of a lower surface of the pad trench PT may be lower than that of the upper surface (e.g., the uppermost surface) of the spacer structure 140. Moreover, at least a portion of the pad trench PT may overlap at least a portion of the spacer structure 140 in the fourth direction Z. In some embodiments, the pad trench PT may overlap a portion of the spacer structure 140 and a portion of the first capping pattern 138 in the fourth direction Z. Accordingly, the plurality of landing contacts 150 may be formed as the isolated areas defined by the first capping patterns 138, the spacer structures 140, and the insulating fences 170.

In some embodiments, the isolation insulating film 180 may disposed in (e.g., filling) the pad trench. The isolation insulating film 180 may include, for example, silicon oxide, silicon oxynitride, silicon nitride, and/or a low-k material with a lower dielectric constant than that of silicon oxide. However, the present disclosure is not limited thereto. The plurality of landing contacts 150 may be electrically insulated from each other via the isolation insulating film 180.

In some embodiments, the plurality of landing contacts 150 isolated from each other via the pad trench PT may be arranged in a honeycomb structure. The landing contacts 150 arranged in the honeycomb structure may further improve the integration of the semiconductor memory device.

The capacitor structure 190 may be formed on the isolation insulating film 180 and the landing contact 150. The capacitor structure 190 may contact the upper surface (e.g., the uppermost surface) of the landing contact 150. For example, the isolation insulating film 180 may be patterned so as to expose at least a portion of the upper surface (e.g., the uppermost surface) of the landing contact 150. The capacitor structure 190 may contact the portion of the landing contact 150 not covered with the isolation insulating film 180. The capacitor structure 190 may store therein data under control of the first conductive pattern 130 acting as the bit line and the second conductive pattern 160 acting as the word line.

In some embodiments, the capacitor structure 190 may include a lower electrode pattern 192, a capacitor dielectric film 194, and an upper electrode pattern 196 sequentially stacked on the landing contact 150. The capacitor structure 190 may store charges in the capacitor dielectric film 194 using a potential difference generated between the lower electrode pattern 192 and the upper electrode pattern 196.

Each of the lower electrode pattern 192 and the upper electrode pattern 196 may include, for example, doped polysilicon, metal, and/or metal nitride. However, the present disclosure is not limited thereto. For example, the capacitor dielectric film 194 may include, for example, silicon oxide, silicon oxynitride, silicon nitride, and/or a high-k material with a higher dielectric constant than that of silicon oxide. However, the present disclosure is not limited thereto.

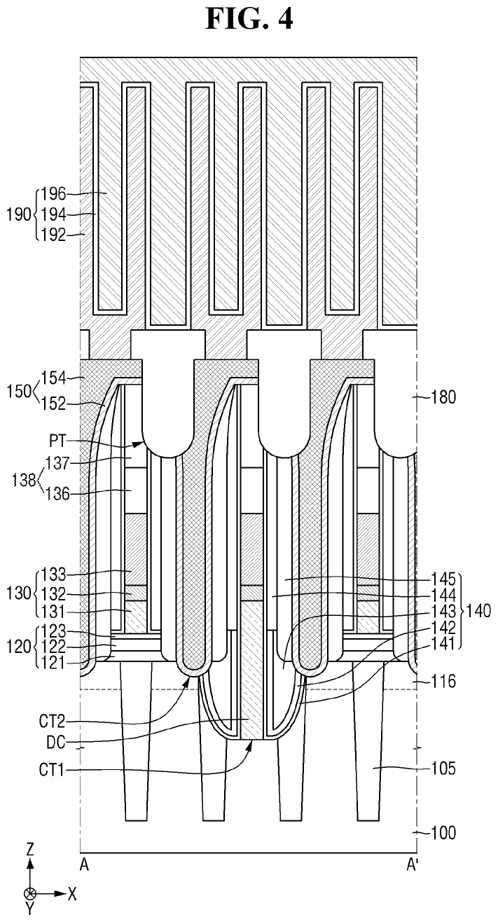

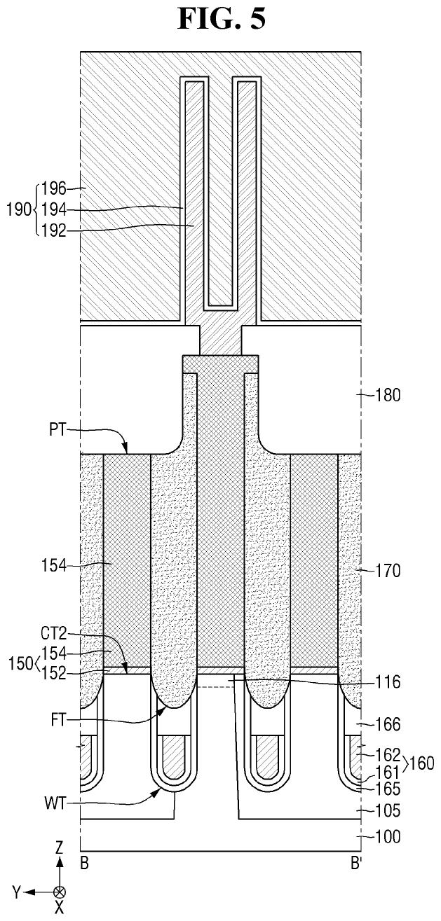

FIG. 4 is a cross-sectional view taken along A-A′ of FIG. 1 according to some embodiments. FIG. 5 is a cross-section taken along B-B′ of FIG. 1 according to some embodiments. For convenience of description, those duplicate with the descriptions as set forth above using FIGS. 1 to 3 may be briefly set forth or may be omitted.

Referring to FIG. 1, FIG. 4, and FIG. 5, a semiconductor memory device according to some embodiments may include an impurity area 116.

The impurity area 116 may be formed in an upper portion of the substrate 100. The impurity area 116 may be formed by doping impurities into the upper portion of the substrate 100. For example, the impurity area 116 may be formed by an ion implantation process performed into the upper portion of the substrate 100. However, the present disclosure is not limited thereto. In some embodiments, the impurity area 116 may be a p-type impurity area doped with a p-type impurity, such as B, In, Ga, or Al. In some embodiments, the impurity area 116 may be an n-type impurity area doped with an n-type impurity, such as P, Sb, or As.

In some embodiments, the second contact trench CT2 may expose the impurity area 116. For example, the second contact trench CT2 may include a recess (e.g., concavely recessed portion) in an upper portion of the impurity area 116. The landing contact 150 may be formed in the second contact trench CT2 and in contact with the impurity area 116. For example, the barrier metal film 152 may be disposed on (e.g., conformally extend along) an upper surface of the impurity area 116. The barrier metal film 152 may be in contact (e.g., direct contact) with the impurity area 116.

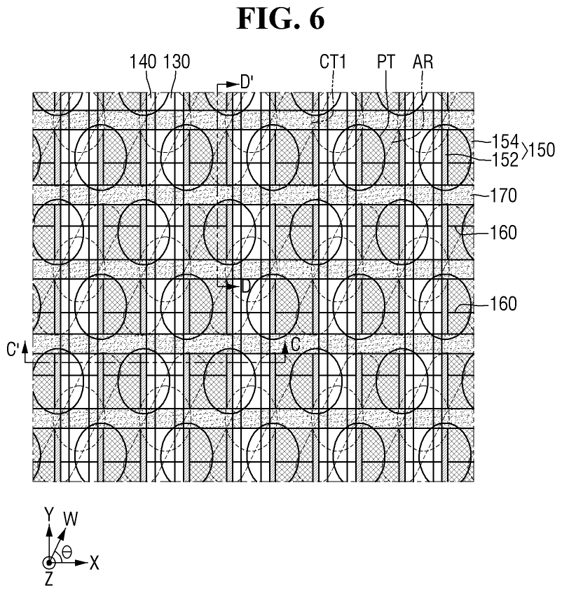

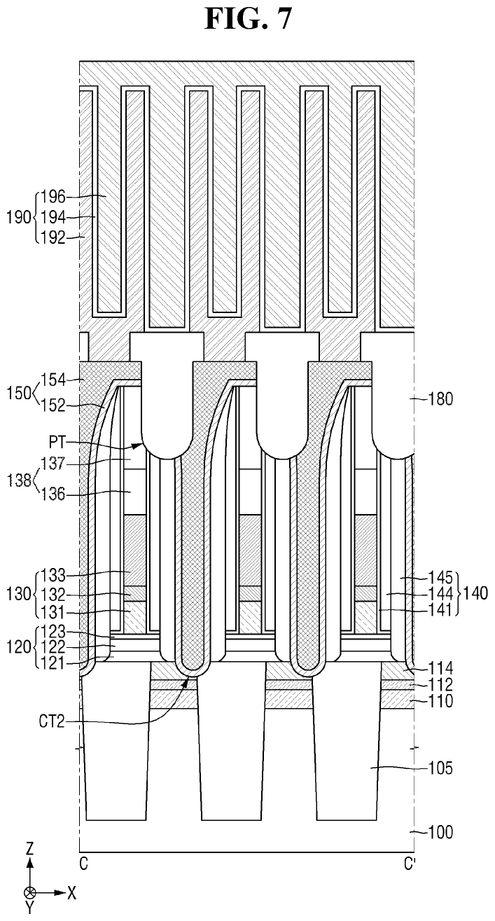

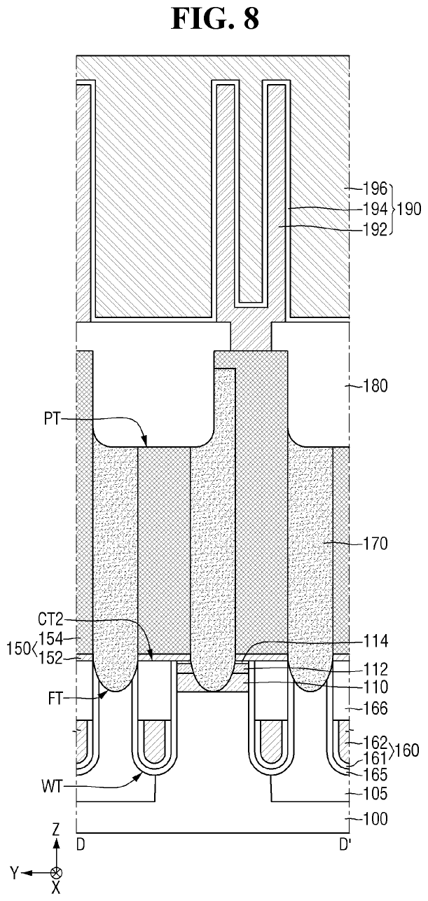

FIG. 6 is a layout diagram for illustrating a semiconductor memory device according to some embodiments. FIG. 7 is a cross-sectional view taken along C-C′ of FIG. 6 according to some embodiments. FIG. 8 is a cross-sectional view taken along D-D′ of FIG. 6 according to some embodiments. For convenience of description, those duplicate with the descriptions as set forth above using FIGS. 1 to 3 may be briefly set forth or may be omitted.

Referring to FIGS. 6 to 8, in a semiconductor memory device according to some embodiments, a plurality of active areas AR may be arranged in a lattice structure.

For example, some of the plurality of active areas AR may constitute a series of columns arranged along the first direction Y, and some of the plurality of active areas AR may constitute a series of rows arranged along the second direction X. The active areas AR arranged in the lattice structure may further improve the integration of the semiconductor memory device.

In some embodiments, each active area AR may be formed in a form of a diagonally extending bar. For example, each active area AR may have a bar shape extending in the third direction W. In some embodiments, a distal end of one active area AR among the plurality of active areas AR may be disposed adjacent to a distal end of another active area AR among the plurality of active areas AR.

In some embodiments, the first contact trench CT1 may expose the center (e.g., the center portion) of each active area AR. Accordingly, the direct contact DC may be electrically connected (e.g., connected) to the center (e.g., the center portion) of the active area AR.

In some embodiments, the second contact trench CT2 may expose each of both opposing ends of each active area AR. Accordingly, the landing contact 150 may be electrically connected (e.g., connected) to each of both opposing ends of the active area AR.

In some embodiments, two second conductive patterns 160 may intersect one active area AR. For example, two second conductive patterns 160 may be respectively disposed on both opposing sides of the direct contact DC electrically connected (e.g., connected) to the center (e.g., center portion) of one active area AR. These two second conductive patterns 160 may share one direct contact DC.

In some embodiments, each of some of the plurality of insulating fences 170 may overlap the center (e.g., center portion) of each active area AR in the fourth direction Z. In some embodiments, each of the others of the plurality of insulating fences 170 may be disposed between two active areas AR spaced apart from each other in the first direction Y in a plan view. In some embodiments, the insulating fence 170 may not overlap the second conductive pattern 160 in the fourth direction Z. For example, the insulating fence 170 may be formed on the active area AR and/or the element isolation pattern 105. In some embodiments, at least a portion of the insulating fence 170 may overlap the second conductive pattern 160 in the fourth direction Z. In some embodiments, at least a portion of the insulating fence 170 may not overlap the second conductive pattern 160 in the fourth direction Z.

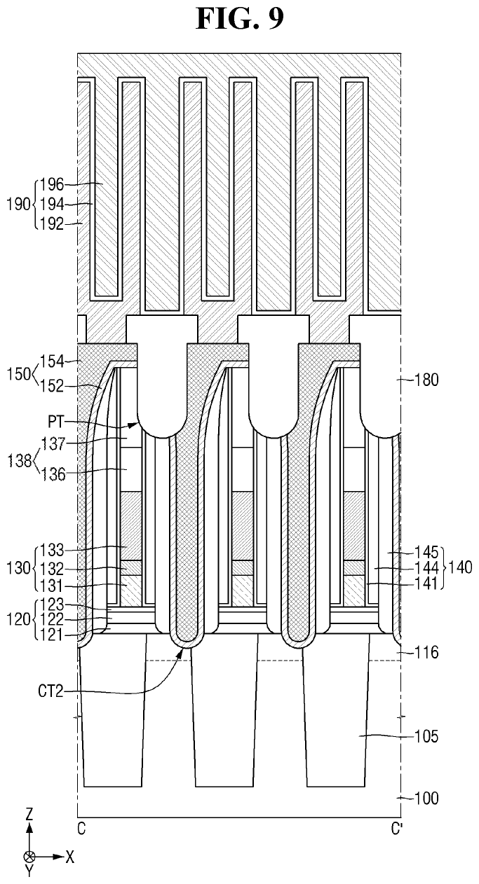

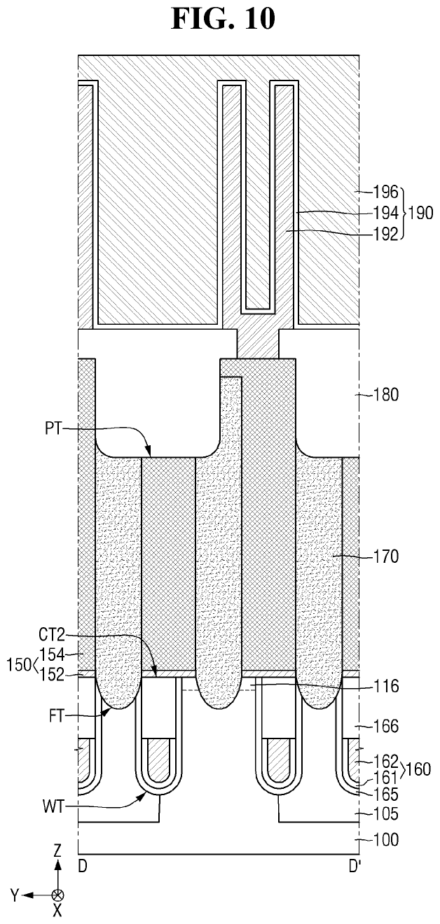

FIG. 9 is a cross-section taken along C-C′ of FIG. 6 according to some embodiments. FIG. 10 is a cross-section taken along D-D′ of FIG. 6 according to some embodiments. For convenience of description, those duplicate with the descriptions as set forth above using FIGS. 1 to 8 may be briefly set forth or may be omitted.

Referring to FIG. 6, FIG. 9, and FIG. 10, a semiconductor memory device according to some embodiments may include the impurity area 116.

Since the impurity area 116 is similar to that as described above using FIG. 1, FIG. 4 and FIG. 5, a detailed description thereof may be omitted below.

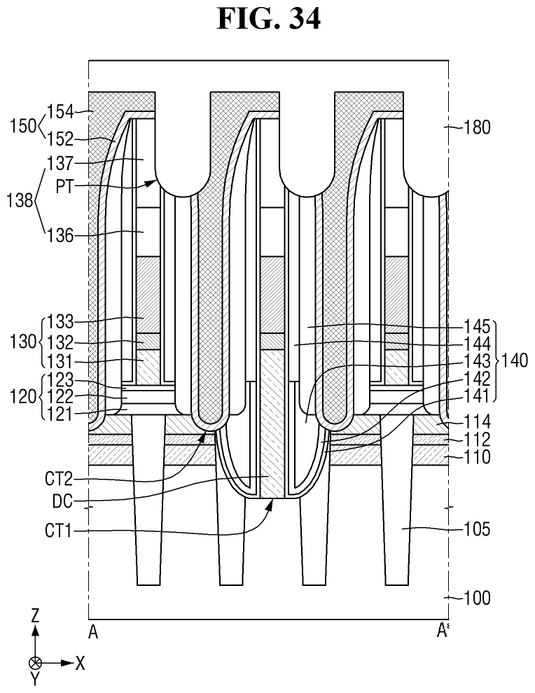

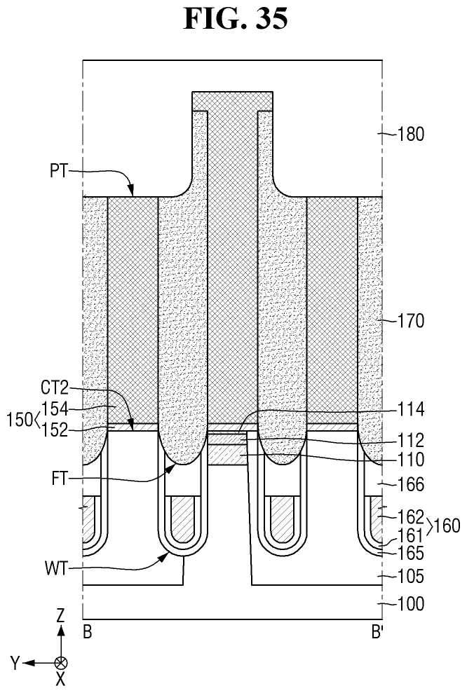

Hereinafter, with reference to FIGS. 1 to 44, a method of manufacturing a semiconductor memory device according to some embodiments is described.

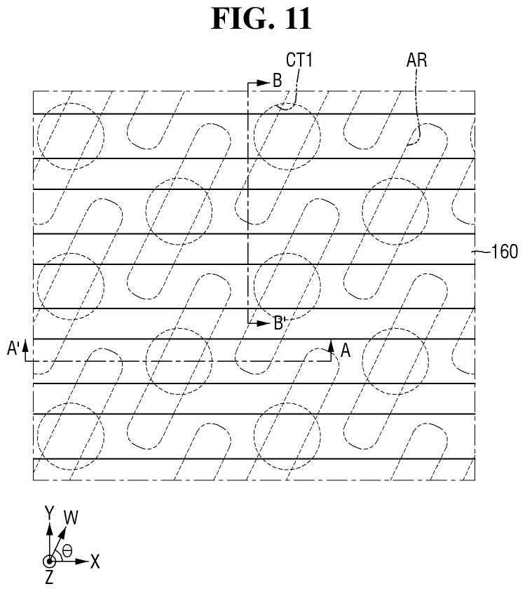

FIG. 11 to FIG. 35 are diagrams of intermediate structures corresponding to intermediate steps for illustrating a method for a manufacturing a semiconductor memory device according to some embodiments. For convenience of description, those duplicate with the descriptions as set forth above using FIGS. 1 to 10 may be briefly set forth or may be omitted.

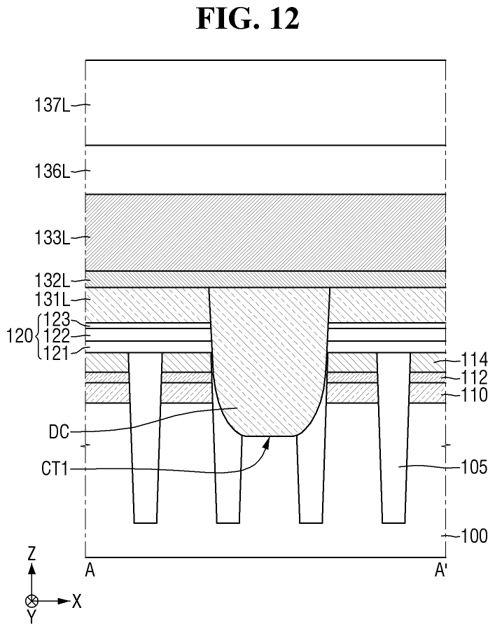

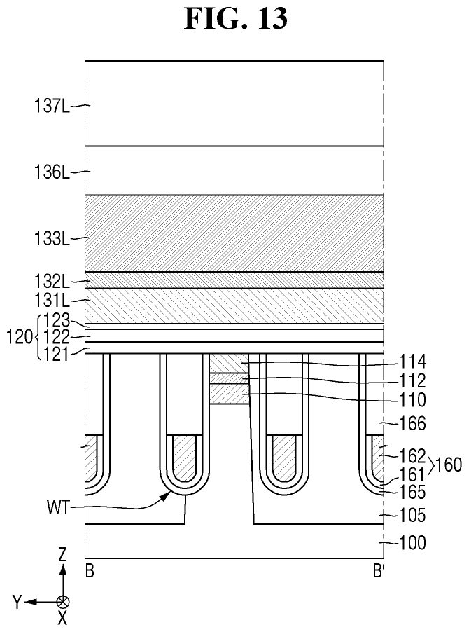

Referring to FIG. 11 to FIG. 13, the element isolation pattern 105, the second conductive pattern 160, the gate dielectric film 165, the second capping pattern 166, the base insulating film 120, a first conductive film 131L, the direct contact DC, a second conductive film 132L, a third conductive film 133L, a first capping film 136L, and a second capping film 137L may be formed on the substrate 100. For reference, FIG. 12 is a cross-sectional view taken along A-A′ of FIG. 11, and FIG. 13 is a cross-sectional view taken along B-B′ of FIG. 11.

For example, the element isolation pattern 105 defining a plurality of active areas AR may be formed in the substrate 100. For example, the element isolation pattern 105 may be adjacent to one of the plurality of active areas AR. In some embodiments, the base semiconductor film 110, the base silicide film 112, and the base metal film 114 may be sequentially formed on the substrate 100. After the base metal film 114 has been formed, the element isolation pattern 105 may be formed to define the plurality of active areas AR in the base semiconductor film 110, the base silicide film 112, and the base metal film 114.

Subsequently, the gate trench WT extending in the second direction X may be formed in the substrate 100 and the element isolation pattern 105. The gate dielectric film 165, the second conductive pattern 160, and the second capping pattern 166 may be disposed in the gate trench WT. The gate dielectric film 165 may extend along at least a portion of the profile of the gate trench WT. The second conductive pattern 160 may fill a portion of the gate trench WT while being disposed on the gate dielectric film 165. The second capping pattern 166 may fill another portion of the gate trench WT while being disposed on the gate dielectric film 165 and the second conductive pattern 160.

Subsequently, the first insulating film 121, the second insulating film 122, the third insulating film 123, and the first conductive film 131L may be sequentially formed on the substrate 100 and the element isolation pattern 105. Subsequently, the first contact trench CT1 exposing the first portion of the active area AR (for example, the center portion of the active area AR) may be formed. Subsequently, the direct contact DC filling the first contact trench CT1 may be formed. Subsequently, the second conductive film 132L, the third conductive film 133L, the first capping film 136L, and the second capping film 137L may be sequentially formed on the first conductive film 131L.

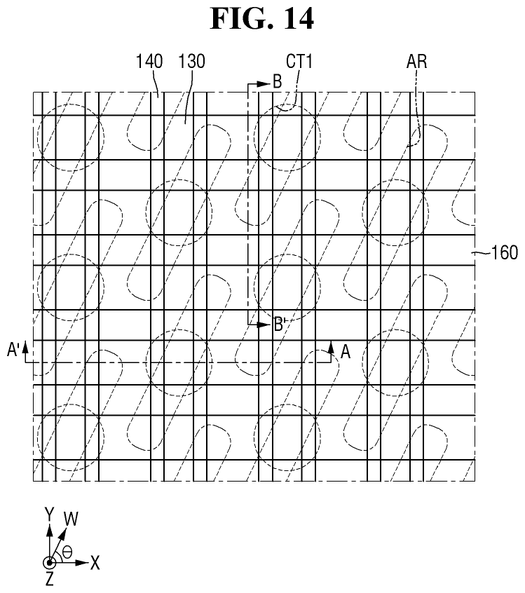

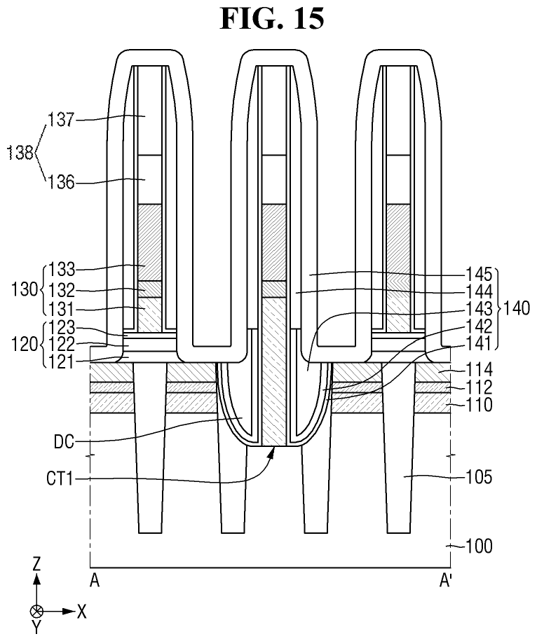

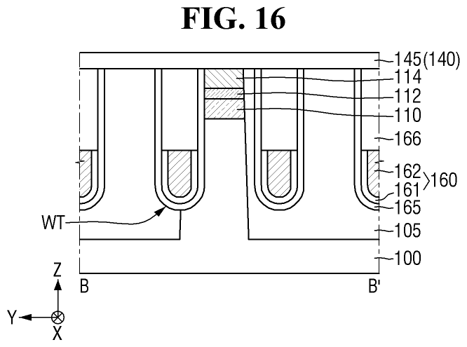

Referring to FIGS. 14 to 16, the first conductive pattern 130, the first capping pattern 138, and the spacer structure 140 may be formed. For reference, FIG. 15 is a cross-sectional view taken along A-A′ of FIG. 14, and FIG. 16 is a cross-sectional view taken along B-B′ of FIG. 14.

For example, a patterning process on the first conductive film 131L, the direct contact DC, the second conductive film 132L, the third conductive film 133L, the first capping film 136L, and the second capping film 137L of FIGS. 11 to 13 may be performed. Thus, the first conductive pattern 130 and the first capping pattern 138 extending (e.g., in an elongate manner) in the first direction Y may be formed on the substrate 100.

Subsequently, the spacer structure 140 may be formed on the side surfaces of the first conductive pattern 130 and the side surface of the first capping pattern 138. For example, the base spacer 141 disposed on (e.g., conformally extending on) the first conductive pattern 130 and the first capping pattern 138 may be formed. Subsequently, the first lower spacer 142 and the second lower spacer 143 may be sequentially formed on the base spacer 141 and in the first contact trench CT1. Then, the first side spacer 144 disposed on (e.g., conformally extending along) the base spacer 141, the first lower spacer 142, and the second lower spacer 143 may be formed. Subsequently, an etching process may be performed to remove a portion of the base insulating film 120 disposed between adjacent ones of the plurality of first conductive patterns 130. In the etching process, a portion of the first side spacer 144 extending along the outer side surface of the base spacer 141 may not be removed but may remain. Subsequently, the second side spacer 145 may be formed so as to be disposed on (e.g., conformally extend) on the first side spacer 144 (e.g., on a side surface of the first side spacer 144).

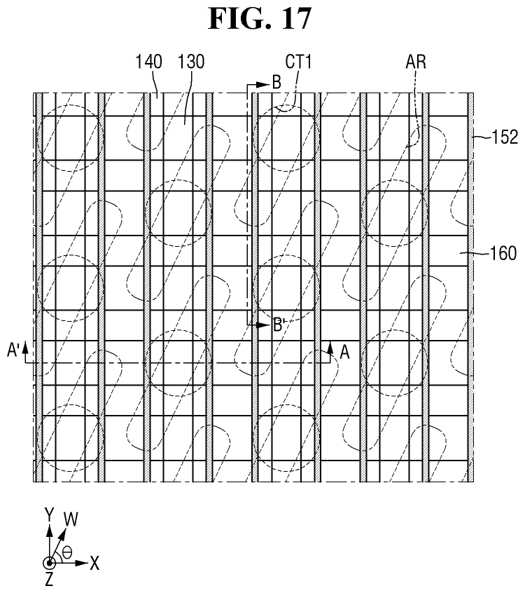

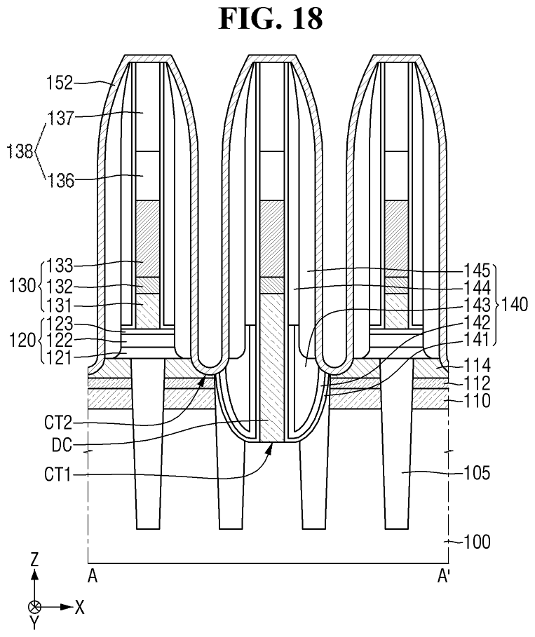

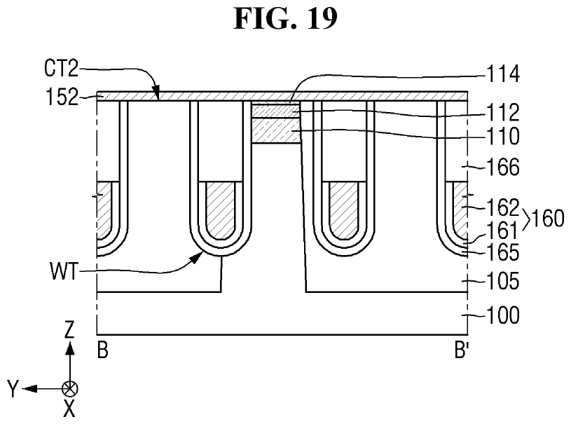

Referring to FIGS. 17 to 19, the barrier metal film 152 may be formed on the spacer structure 140. For reference, FIG. 18 is a cross-sectional view taken along A-A′ of FIG. 17, and FIG. 19 is a cross-sectional view taken along B-B′ of FIG. 17.

For example, the second contact trench CT2 extending in the first direction Y may be formed on the side surface of the spacer structure 140. The second contact trench CT2 may expose the second portion of the active area AR (for example, each of both opposing ends of the active area AR). Subsequently, the barrier metal film 152 disposed on (e.g., conformally extending along the profile of) the second contact trench CT2 may be formed. In some embodiments, the second contact trench CT2 may expose the base metal film 114. In this case, the barrier metal film 152 may contact the base metal film 114.

The barrier metal film 152 may include, for example, titanium (Ti), tantalum (Ta), tungsten (W), nickel (Ni), cobalt (Co), platinum (Pt), alloys thereof, and/or nitrides thereof. However, the present disclosure is not limited thereto. In some embodiments, the barrier metal film 152 may include a titanium nitride film.

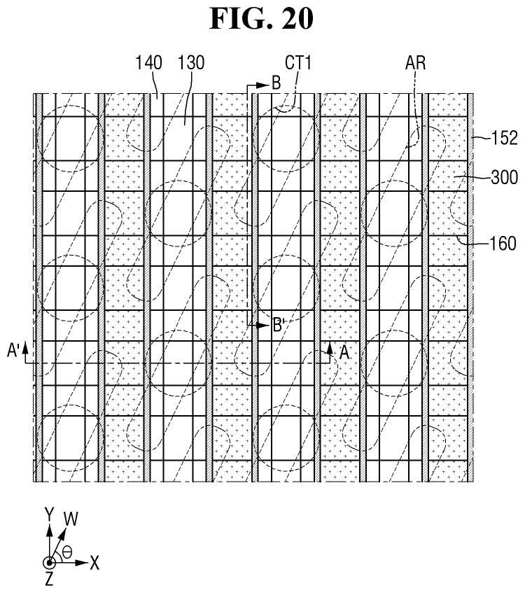

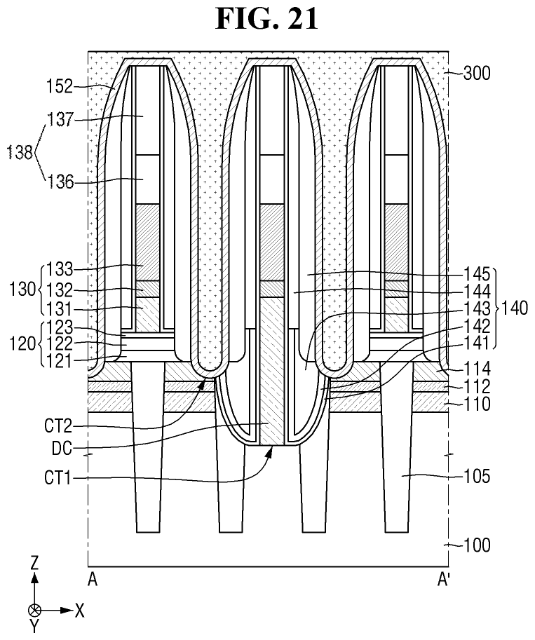

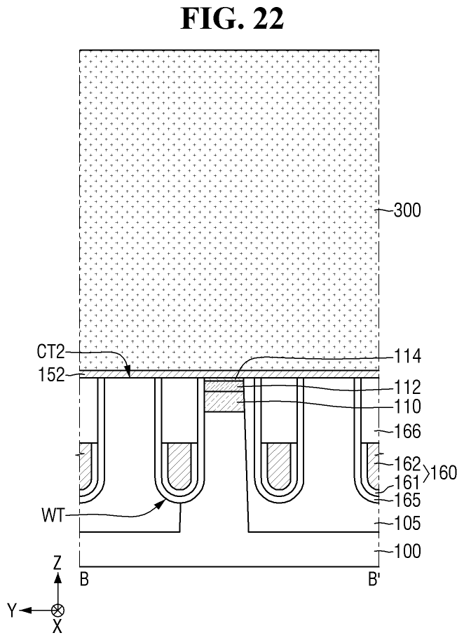

Referring to FIG. 20 to FIG. 22, a sacrificial mold 300 may be formed on the base metal film 114. For reference, FIG. 21 is a cross-sectional view taken along A-A′ of FIG. 20, and FIG. 22 is a cross-sectional view taken along B-B′ of FIG. 20.

The sacrificial mold 300 may be formed on the base metal film 114 so as to fill at least a portion of a space between adjacent ones of the plurality of first conductive patterns 130. For example, the sacrificial mold 300 may be disposed in (e.g., may fill) the second contact trench CT2. The sacrificial mold 300 may be on the barrier metal film 152. The sacrificial mold 300 may include a material having an etch selectivity with respect to the insulating fence 170 to be formed in a subsequent process. For example, the insulating fence 170 may include a silicon nitride film, and the sacrificial mold 300 may include a silicon oxide film.

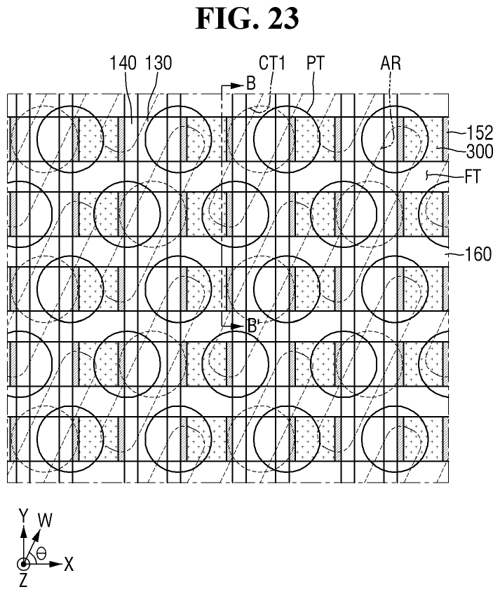

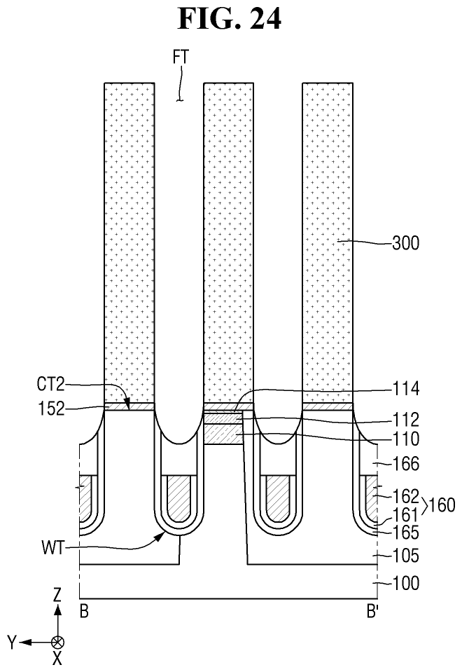

Referring to FIG. 23 and FIG. 24, the fence trench FT may be formed in the barrier metal film 152 and the sacrificial mold 300. For reference, FIG. 24 is a cross-sectional view taken along B-B′ of FIG. 23.

The fence trench FT may extend through the barrier metal film 152 and the sacrificial mold 300. The fence trench FT may extend (e.g., extend in an elongate manner) in the second direction X so as to cut the barrier metal film 152 and the sacrificial mold 300. A plurality of fence trenches FT may be spaced apart from each other in the first direction Y and may extend side by side (e.g., in a parallel manner to each other) in the second direction X. In some embodiments, the plurality of fence trenches FT may be spaced apart from each other by an equal spacing.

In some embodiments, the fence trench FT may overlap the second conductive pattern 160 in the fourth direction Z. In some embodiments, a vertical level of a lowermost portion of the fence trench FT may be lower than that of a lower surface of the barrier metal film 152. For example, the fence trench FT may extend through the barrier metal film 152 so as to expose the second capping pattern 166.

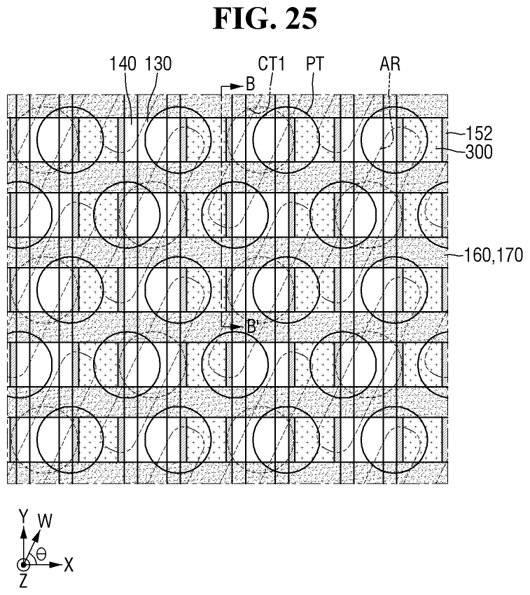

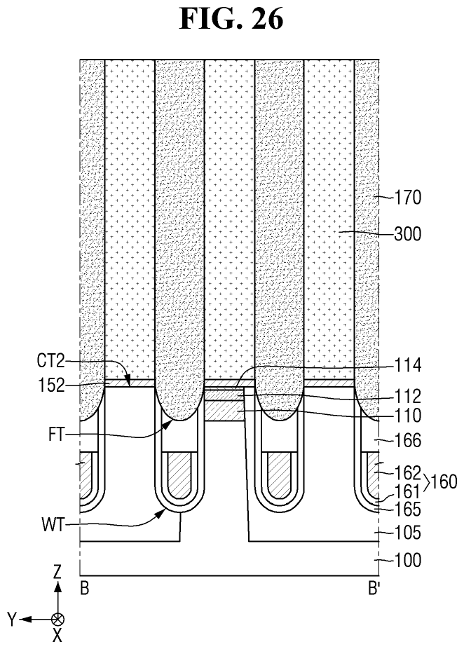

Referring to FIG. 25 and FIG. 26, the insulating fence 170 may be formed in the fence trench FT. For reference, FIG. 26 is a cross-sectional view taken along B-B′ of FIG. 25.

Thus, the insulating fence 170 may extend (e.g., extend in an elongate manner) in the second direction X so as to cut the barrier metal film 152 and the sacrificial mold 300. A plurality of first conductive patterns 130 and a plurality of insulating fences 170 intersecting each other may define a plurality of isolated areas therebetween. The barrier metal film 152 and the sacrificial mold 300 may be formed in each of the isolated areas. The spacer structure 140 may electrically insulate the first conductive pattern 130 and the barrier metal film 152 from each other.

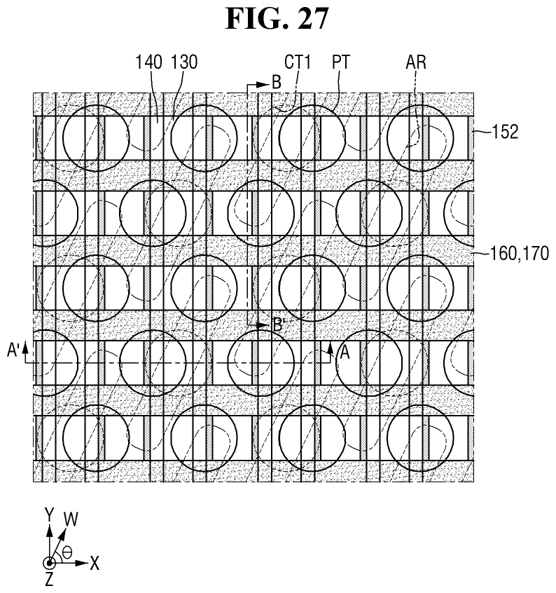

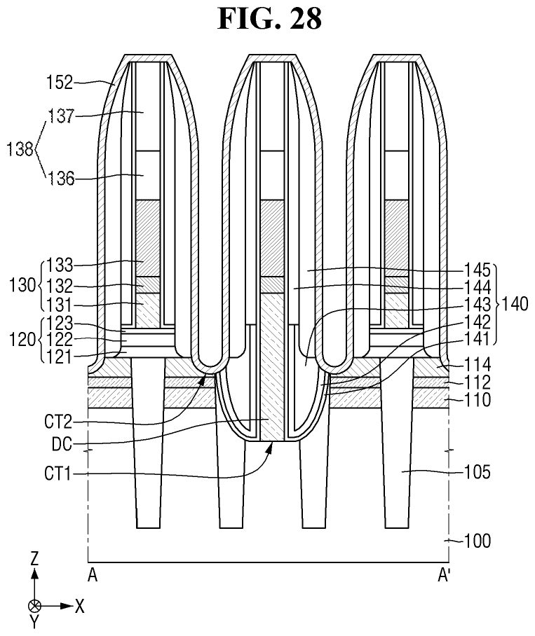

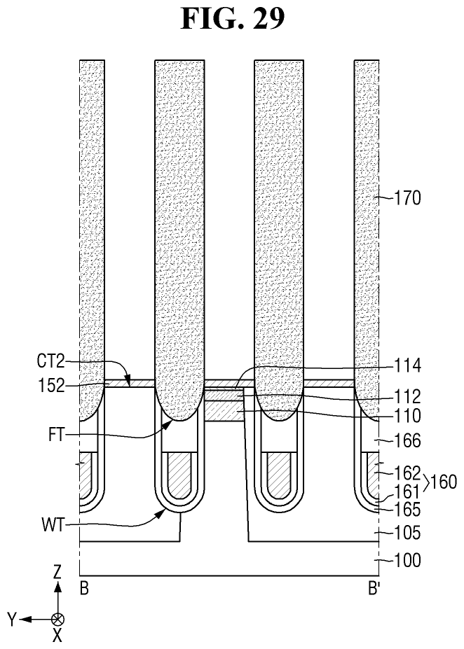

Referring to FIG. 27 to FIG. 29, the sacrificial mold 300 may be removed. For reference, FIG. 28 is a cross-sectional view taken along A-A′ of FIG. 27, and FIG. 29 is a cross-sectional view taken along B-B′ of FIG. 27.

Since the sacrificial mold 300 may have an etching selectivity with respect to the insulating fence 170, the sacrificial mold 300 may be selectively removed. Removing the sacrificial mold 300 may include, for example, a wet etching process and/or a dry etching process. However, the present disclosure is not limited thereto.

While the sacrificial mold 300 is being removed, the barrier metal film 152 may protect the active area AR and/or the element isolation pattern 105. Specifically, since the barrier metal film 152 is formed before the sacrificial mold 300 is formed, the barrier metal film 152 may prevent the active area AR and/or the element isolation pattern 105 from being damaged by the etching process that removes the sacrificial mold 300.

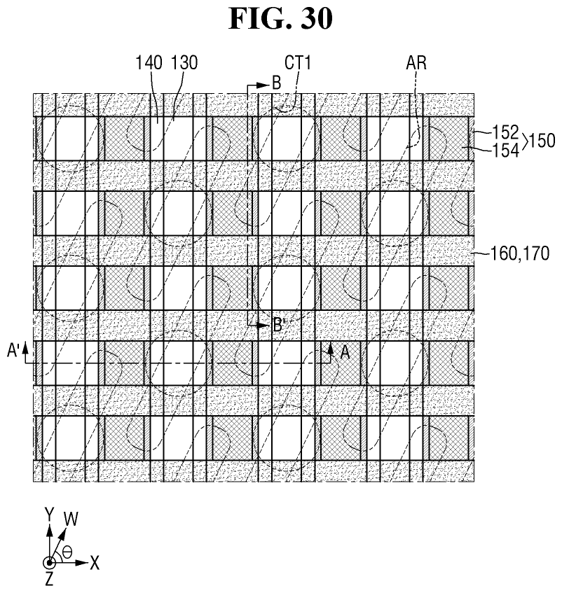

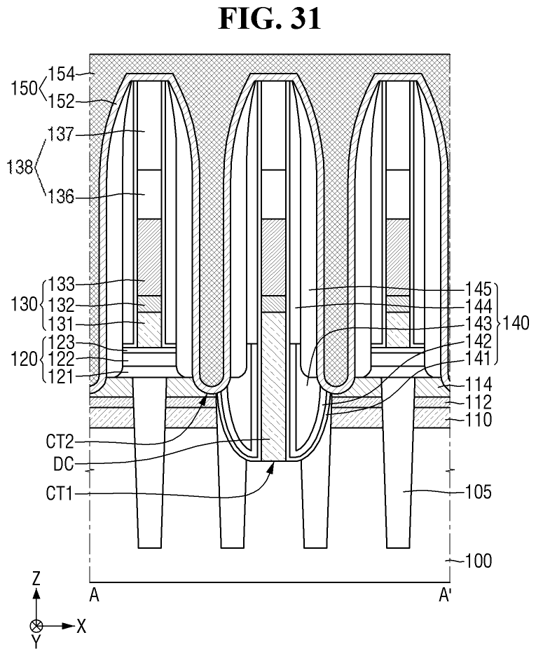

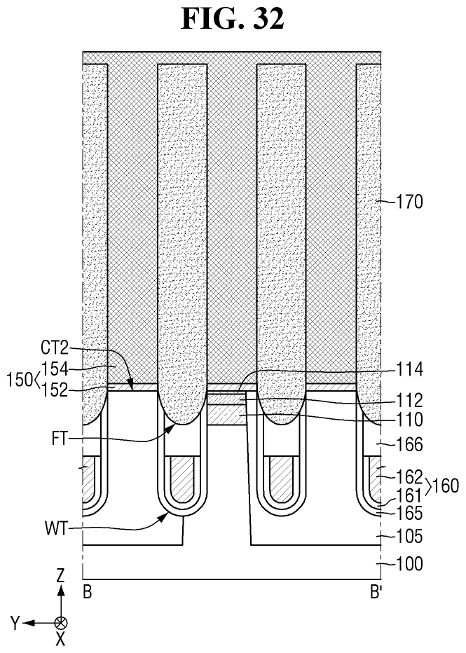

Referring to FIGS. 30 to 32, the filling metal film 154 may be formed on the barrier metal film 152. For reference, FIG. 31 is a cross-sectional view taken along A-A′ of FIG. 30, and FIG. 32 is a cross-sectional view taken along B-B′ of FIG. 30.

Thus, the filling metal film 154 may fill at least a portion of a space between adjacent ones of the plurality of first conductive patterns 130 and a space between adjacent ones of the plurality of insulating fences 170. The filling metal film 154 may include a conductive metal material, for example, tungsten (W), molybdenum (Mo), ruthenium (Ru), cobalt (Co), nickel (Ni), and/or combinations thereof. However, the present disclosure is not limited thereto. In some embodiments, the filling metal film 154 may include tungsten (W).

In some embodiments, the vertical level of the upper surface (e.g., the uppermost surface) of the filling metal film 154 may be higher than the vertical level of the upper surface (e.g., the uppermost surface) of the first capping pattern 138. In some embodiments, the vertical level of an upper surface (e.g., an uppermost surface) of the filling metal film 154 may be higher than that of an upper surface (e.g., an uppermost surface) of the insulating fence 170. In some embodiments, the filling metal film 154 may be a unitary structure that is integrally formed and may extend from a vertical level lower than that of a lower surface of the first conductive pattern 130 (for example, a lower surface of the first conductive line 131) to a vertical level higher than that of the upper surface of the insulating fence 170.

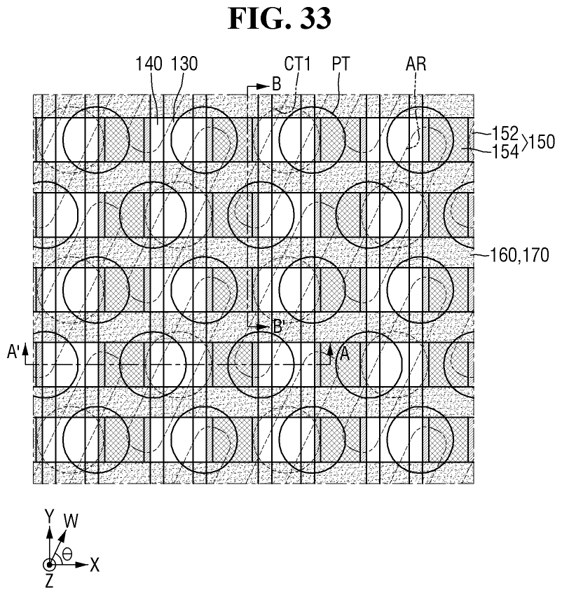

Referring to FIG. 33 to FIG. 35, the pad trench PT and the isolation insulating film 180 may be formed.

The pad trench PT may isolate the upper portions of the landing contacts 150 from each other. For example, the pad trench PT may extend from the upper surface of the landing contact 150, while the vertical level of the lower surface of the pad trench PT may be lower than that of the upper surface (e.g., the uppermost surface) of the spacer structure 140. Moreover, at least a portion of the pad trench PT may overlap at least a portion of the spacer structure 140 in the fourth direction Z. Accordingly, the plurality of landing contacts 150 defined as the isolated areas isolated from each other via the first capping pattern 138, the spacer structure 140, and the insulating fence 170 may be formed. For example, the plurality of landing contacts 150 may be spaced apart from each other via the first capping pattern 138, the spacer structure 140, and the insulating fence 170. Subsequently, the isolation insulating film 180 disposed in (e.g., filling) the pad trench PT may be formed.

Subsequently, referring to FIGS. 1 to 3, the capacitor structure 190 may be formed on the isolation insulating film 180 and the landing contact 150. In this way, the semiconductor memory device as described above using FIGS. 1 to 3 may be manufactured.

In order to improve the integration and the performance of the semiconductor memory device including the capacitor, a metal material that replaces a semiconductor material such as polysilicon as a material of a contact (hereinafter, the landing contact) connecting the active area and the capacitor to each other is being studied. However, unlike the semiconductor material such as polysilicon, the metal material has high etching process difficulty. Thus, it may be difficult to implement the landing contacts as a plurality of isolated areas via the etching process of the metal material. For this reason, a scheme of first forming the isolated areas using a sacrificial mold, and filling the isolated areas with a metal material may be proposed. However, in this scheme, the active area and/or the element isolation pattern may be damaged in the process of removing the sacrificial mold. This causes deterioration in performance and reliability of the semiconductor memory device.

However, in the semiconductor memory device according to some embodiments, the landing contact 150 made of a metal material may be provided using the barrier metal film 152 and the sacrificial mold 300. Specifically, as described above, the barrier metal film 152 is formed before the sacrificial mold 300 is formed, and thus may prevent the active area AR and/or the element isolation pattern 105 from being damaged by the etching process that removes the sacrificial mold 300.

Moreover, as the barrier metal film 152 is already in contact with the active area AR, the filling metal film 154 formed on the barrier metal film 152 may be made of the metal material and may be integrally formed and may extend to a vertical level higher than that of the upper surface of the insulating fence 170. Thus, the semiconductor memory device with improved integration, performance, and reliability may be provided.

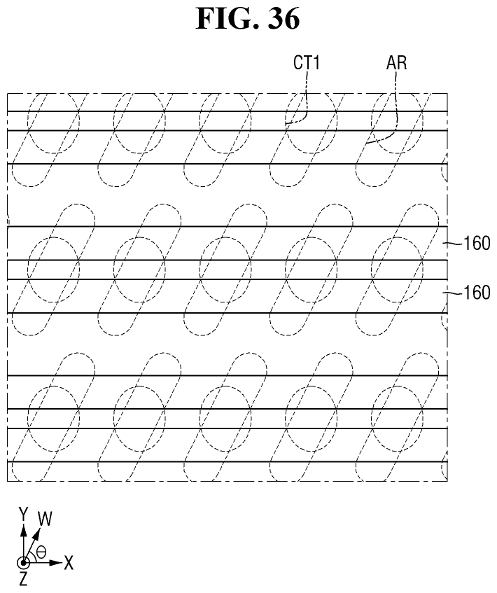

FIG. 36 to FIG. 44 are diagrams of intermediate structures corresponding to intermediate steps for illustrating a method for manufacturing a semiconductor memory device according to some embodiments. For convenience of description, those duplicate with the descriptions as set forth above using FIGS. 1 to 35 may be briefly set forth or may be omitted.

Referring to FIG. 36, the active area AR, the first contact trench CT1, and the second conductive pattern 160 may be formed. Forming the active area AR, the first contact trench CT1, and the second conductive pattern 160 is similar to that as described above using FIGS. 11 to 13. Thus, detailed descriptions thereof may be omitted below.

A plurality of active areas AR may be arranged in a lattice structure. In some embodiments, the first contact trench CT1 may expose the center (e.g., center portion) of each active area AR. In some embodiments, two second conductive patterns 160 may extend across one active area AR.

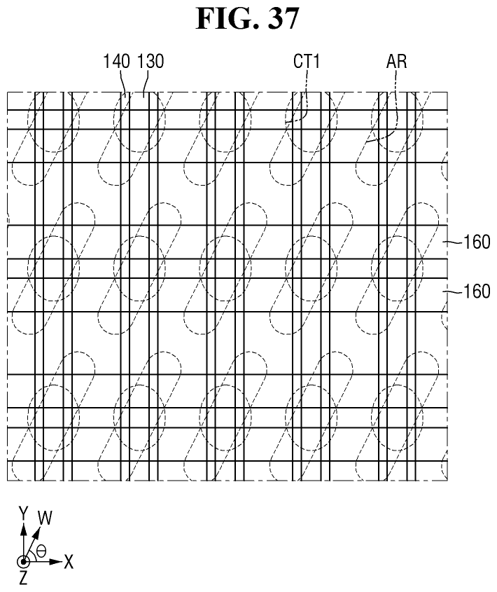

Referring to FIG. 37, the first conductive pattern 130 and the spacer structure 140 may be formed. Forming the first conductive pattern 130 and the spacer structure 140 is similar to that as described above using FIGS. 14 to 16. Thus, a detailed description thereof may be omitted below.

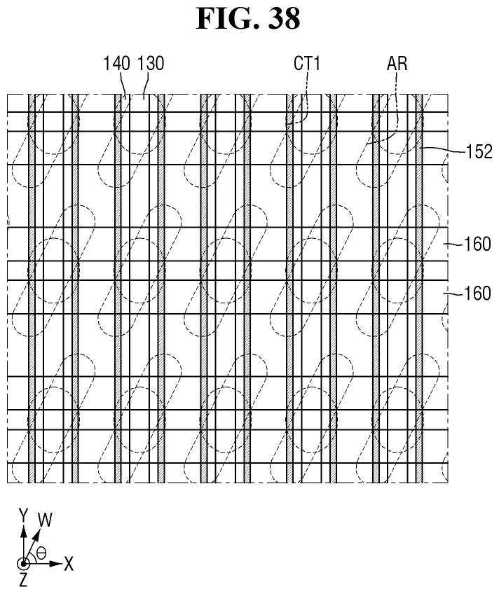

Referring to FIG. 38, the barrier metal film 152 may be formed on the spacer structure 140. Forming the barrier metal film 152 is similar to that as described above using FIGS. 17 to 19. Thus, detailed descriptions thereof may be omitted below.

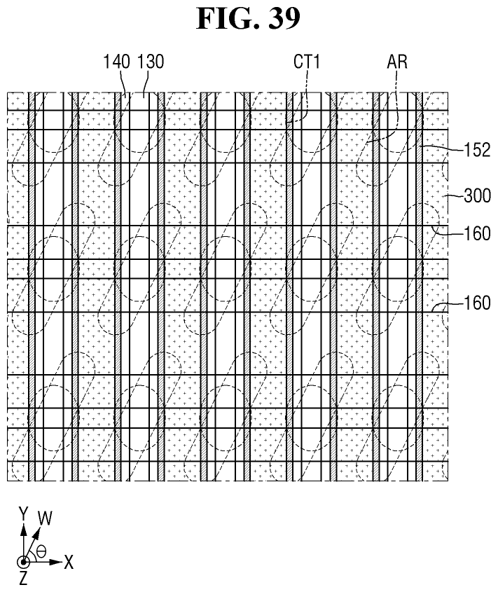

Referring to FIG. 39, the sacrificial mold 300 may be formed on the base metal film 114. Forming the sacrificial mold 300 is similar to that as described above using FIGS. 20 to 22. Thus, detailed descriptions thereof may be omitted below.

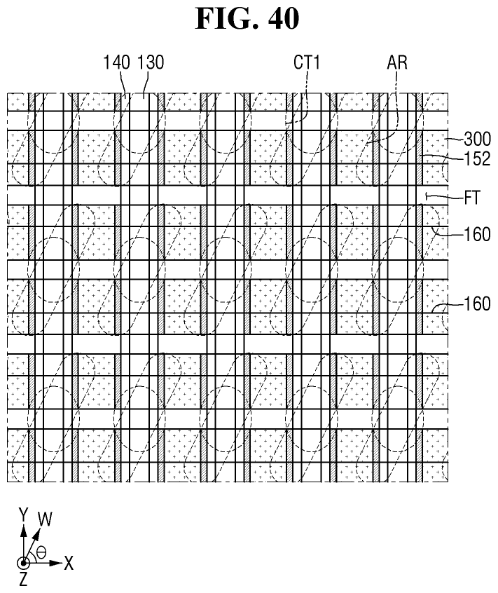

Referring to FIG. 40, the fence trench FT may be formed in the barrier metal film 152 and the sacrificial mold 300. Forming the fence trench FT is similar to that as described above using FIG. 23 and FIG. 24. Thus, detailed descriptions thereof may be omitted below.

In some embodiments, each of some of the plurality of fence trenches FT may overlap the center (e.g., center portion) of each active area AR in the fourth direction Z. In some embodiments, each of the others of the plurality of fence trenches FT may be disposed between two active areas AR arranged along (e.g., spaced apart from each other in) the first direction Y in a plan view. In some embodiments, the fence trench FT may not overlap the second conductive pattern 160 in the fourth direction Z.

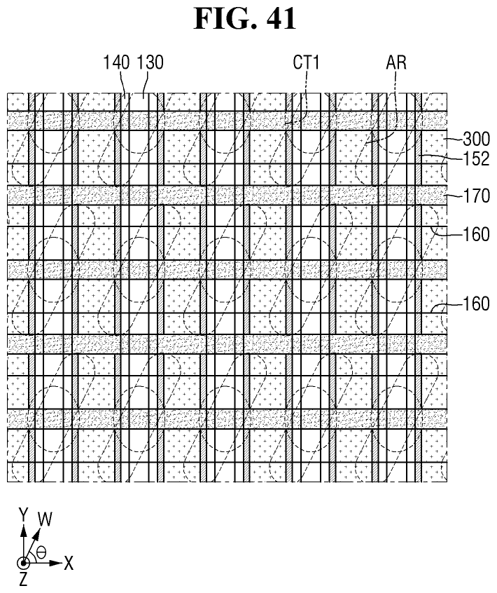

Referring to FIG. 41, the insulating fence 170 may be formed. Forming the insulating fence 170 is similar to that as described above using FIG. 25 and FIG. 26. Thus, detailed descriptions thereof may be omitted below.

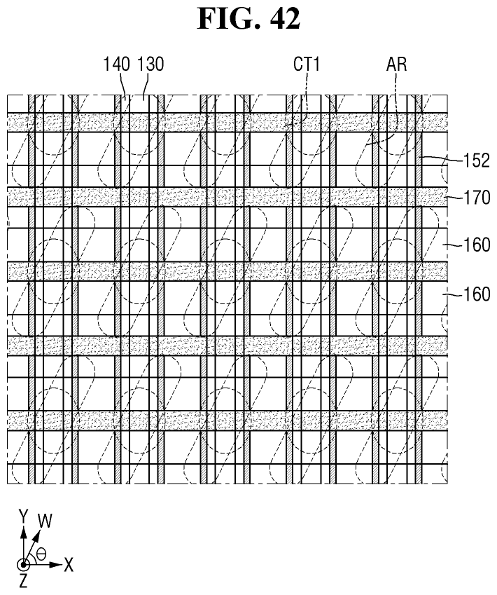

Referring to FIG. 42, the sacrificial mold 300 may be removed. Removing the sacrificial mold 300 is similar to that as described above using FIGS. 27 to 29. Thus, detailed descriptions thereof may be omitted below.

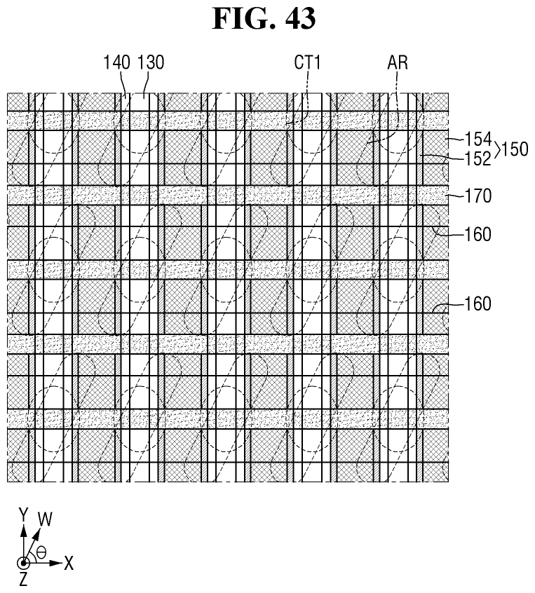

Referring to FIG. 43, the filling metal film 154 may be formed on the barrier metal film 152. Forming the filling metal film 154 is similar to that as described above using FIGS. 30 to 32. Thus, detailed descriptions thereof may be omitted below.

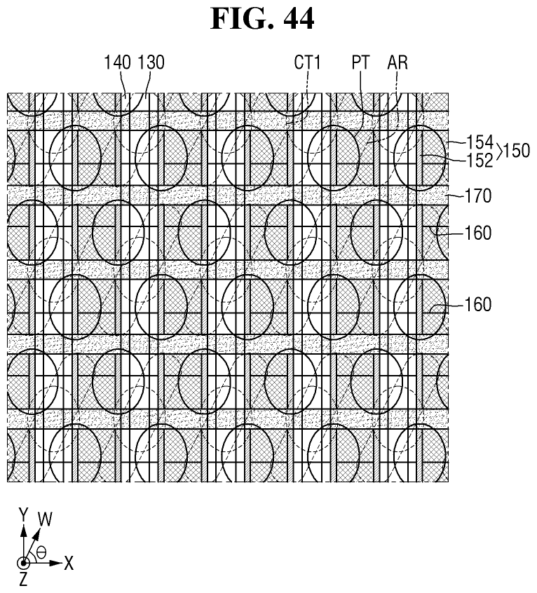

Referring to FIG. 44, the pad trench PT may be formed. Forming the pad trench PT is similar to that as described above using FIGS. 33 to 35. Thus, detailed descriptions thereof may be omitted below.

Subsequently, referring to FIGS. 6 to 8, the capacitor structure 190 may be formed. In this way, the semiconductor memory device as described above using FIGS. 6 to 8 may be manufactured.

Example embodiments are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, embodiments herein should not be construed as limited to the particular shapes illustrated herein but may include deviations in shapes that result, for example, from manufacturing.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Spatially relative terms, such as “beneath,” “below,” “lower,” “above,” “upper,” “higher” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

In one example, when a certain embodiment may be implemented differently, processes or methods may occur in a sequence different from that specified in the description herein. For example, two consecutive processes may actually be executed at the same time. Depending on a related function or operation, the processes may be executed in a reverse sequence. Moreover, a process may be separated into multiple processes and/or may be at least partially integrated.

In descriptions of temporal relationships, for example, temporal precedent relationships between two events such as “after”, “subsequent to”, “before”, etc., another event may occur therebetween unless “directly after”, “directly subsequent” or “directly before” is not indicated.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

The above-disclosed subject matter is to be considered illustrative, and not restrictive, and the appended claims are intended to cover all such modifications, enhancements, and other embodiments, which fall within the scope of the present invention. Thus, to the maximum extent allowed by law, the scope is to be determined by the broadest permissible interpretation of the following claims and their equivalents, and shall not be restricted or limited by the foregoing detailed description.

Although the embodiments of the present disclosure have been described with reference to the accompanying drawings, the present disclosure is not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A semiconductor memory device comprising:
a substrate;
a base insulating film on an upper surface of the substrate;
a plurality of first conductive patterns on the base insulating film and spaced apart from each other, wherein the plurality of first conductive patterns extend in a first direction;
a spacer structure on a side surface of each of the plurality of first conductive patterns;
a barrier metal film on a side surface of the spacer structure, wherein the barrier metal film extends through the base insulating film to be electrically connected to the substrate;
a filling metal film on the barrier metal film, wherein the filling metal film fills at least a portion of a space between adjacent ones of the plurality of first conductive patterns; and
a capacitor structure on the filling metal film, wherein the capacitor structure is electrically connected to the filling metal film.

2. The semiconductor memory device of claim 1, further comprising a plurality of insulating fences on the substrate and spaced apart from each other, wherein the plurality of insulating fences extend in a second direction intersecting the first direction,
wherein the barrier metal film is on a portion of the upper surface of the substrate between adjacent ones of the plurality of insulating fences, and
wherein the filling metal film fills at least a portion of a space between the adjacent ones of the plurality of insulating fences.

3. The semiconductor memory device of claim 2, wherein a side surface of each of the plurality of insulating fences is in contact with the filling metal film.

4. The semiconductor memory device of claim 1, further comprising a capping pattern on an upper surface of each of the plurality of first conductive patterns,
wherein the barrier metal film is on an upper surface of the capping pattern.

5. The semiconductor memory device of claim 4, wherein an upper surface of the filling metal film is farther than the upper surface of the capping pattern from the upper surface of the substrate.

6. The semiconductor memory device of claim 1, further comprising:
a direct contact extending through the base insulating film to electrically connect the substrate and a first conductive pattern among the plurality of first conductive patterns; and
a plurality of second conductive patterns in the substrate, wherein the plurality of second conductive patterns are spaced apart from each other, wherein the plurality of second conductive patterns extend in a second direction intersecting the first direction,
wherein a second conductive pattern among the plurality of second conductive patterns extends across a portion of the substrate between the filling metal film and the direct contact.

7. The semiconductor memory device of claim 1, further comprising abase metal film between the substrate and the base insulating film,
wherein the barrier metal film is in contact with the base metal film.

8. The semiconductor memory device of claim 7, further comprising:
a base semiconductor film between the substrate and the base metal film, wherein the base semiconductor film includes a semiconductor material doped with impurities; and
a base silicide film between the base semiconductor film and the base metal film, wherein the base silicide film includes a metal silicide material.

9. The semiconductor memory device of claim 1, wherein an upper portion of the substrate includes an impurity area doped with impurities,
wherein the barrier metal film is in contact with the impurity area.

10. The semiconductor memory device of claim 1, wherein the barrier metal film includes a metal nitride.

11. A semiconductor memory device comprising:
a substrate;
a first conductive pattern on the substrate, wherein the first conductive pattern extends in a first direction;
a spacer structure on a side surface of the first conductive pattern;
an insulating fence on the substrate, wherein the insulating fence extends in a second direction intersecting the first direction;
a barrier metal film on an upper surface of the substrate and a side surface of the spacer structure, wherein a side surface of the insulating fence includes a portion that is exposed from the barrier metal film;
a filling metal film on the barrier metal film, wherein the filling metal film is on the side surface of the spacer structure and the side surface of the insulating fence; and
a capacitor structure on the filling metal film, wherein the capacitor structure is electrically connected to the filling metal film.

12. The semiconductor memory device of claim 11, wherein an upper surface of the filling metal film is farther than an upper surface of the insulating fence from the upper surface of the substrate.

13. The semiconductor memory device of claim 11, wherein the filling metal film is a unitary structure and extends from below a lower surface of the first conductive pattern, relative to the upper surface of the substrate, to beyond an upper surface of the insulating fence, relative to the upper surface of the substrate.

14. The semiconductor memory device of claim 11, further comprising:
a direct contact electrically connecting the substrate to the first conductive pattern; and
a second conductive pattern in the substrate,
wherein the second conductive pattern extends in the second direction, and
wherein the second conductive pattern extends across a portion of the substrate between the filling metal film and the direct contact.

15. The semiconductor memory device of claim 11, wherein the insulating fence includes silicon nitride.

16. A semiconductor memory device comprising:
a substrate including an active area that is adjacent an element isolation pattern;
a first conductive pattern on an upper surface of the substrate, wherein the first conductive pattern extends in a first direction;
a direct contact electrically connecting the active area to the first conductive pattern;
a spacer structure on a side surface of the first conductive pattern;
an insulating fence on the substrate, wherein the insulating fence extends in a second direction intersecting the first direction;
a landing contact on a side surface of the spacer structure and a side surface of the insulating fence, wherein the landing contact is in contact with the active area;
a capacitor structure on the landing contact, wherein the capacitor structure is electrically connected to the landing contact; and
a second conductive pattern extending in the second direction and extending across a portion of the active area between the direct contact and the landing contact,
wherein the landing contact includes:
a barrier metal film on the upper surface of the substrate and the side surface of the spacer structure; and
a filling metal film on the barrier metal film, wherein the filling metal film is on the side surface of the spacer structure and the side surface of the insulating fence.

17. The semiconductor memory device of claim 16, further comprising:
a capping pattern on an upper surface of the first conductive pattern,
wherein the barrier metal film is on an upper surface of the capping pattern.

18. The semiconductor memory device of claim 17, wherein an upper surface of the filling metal film is higher than an upper surface of the insulating fence and an upper surface of the capping pattern, relative to the upper surface of the substrate.

19. The semiconductor memory device of claim 16, wherein at least a portion of the insulating fence overlaps the second conductive pattern in a third direction that is perpendicular to the upper surface of the substrate.

20. The semiconductor memory device of claim 16, wherein at least a portion of the insulating fence does not overlap the second conductive pattern in a third direction that is perpendicular to the upper surface of the substrate.
